(19) United States
(12) Patent Application Publication
(10) Pub. No.: US 2026/0343918 A1
(43) Pub. Date: Oct. 29, 2026

(54) SHALLOW-TRENCH ISOLATION PROTECTION STRUCTURE FOR NANOSTRUCTURE FIELD-EFFECT TRANSISTOR DEVICE AND METHODS OF FORMING

(71) Applicant: Taiwan Semiconductor Manufacturing Co., Ltd., Hsinchu (TW)

(72) Inventors: Fang Hsuan Hu, Hsinchu (TW); Zhen-Cheng Wu, Taichung (TW); Yen-Chun Huang, Taipei (TW); Tze-Liang Lee, Hsinchu (TW)

(21) Appl. No.: 19/732,498

(22) Filed: Jul. 6, 2026

Related U.S. Application Data
(63) Continuation of application No. 18/926,786, filed on Oct. 25, 2024.
(60) Provisional application No. 63/660,652, filed on Jun. 17, 2024.

(51) Int. Cl. H10D 30/01; H10D 30/00

(52) U.S. Cl. CPC H10D 30/019; H10D 30/501

(57) ABSTRACT

A shallow trench isolation (STI) protection structure is formed on the STI regions of a nanostructure field-effect transistor (NSFET) device. The STI protection structure protects the STI regions during a subsequent selective etching process for removing a disposable material used in a disposable oxide interposer (DOI) process for forming the NSFET device. The STI protection structure may include a single hard mask layer with high etching resistance to the selective etching process. Alternatively, the STI protection structure may have a dual-layered or tri-layered structure with different materials in each sublayer of the STI protection structure. Area-selective atomic layer deposition (AS-ALD) is used to form the STI protection structure such that the STI protection structure is selectively formed on the upper surface of the STI regions.

### PRIORITY CLAIM AND CROSS-REFERENCE

This application is a continuation of U.S. Patent Application No. 18/926,786, filed Oct. 25, 2024 and entitled “Shallow-Trench Isolation Protection Structure for Nanostructure Field-Effect Transistor Device and Methods of Forming,” which claims priority to U.S. Provisional Application No. 63/660,652, filed Jun. 17, 2024 and entitled “Protecting STI Loss From Sheet Formation Through Area Selective Atomic Layer Deposition of STI Capping,” which applications are incorporated herein by reference.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 14C, 15A, 15B, 15C, 16A, 16B, 16C, 17A, 17B, 17C, 18A, 18B, 18C, 19A, 19B, 19C, 20A, 20B, 20C, 21A, 21B, 22A, 22B, 23A, and 23B, are cross-sectional views of a portion of a nanostructure field-effect transistor (NSFET) device at various stages of manufacturing, in accordance with an embodiment.

FIGS. 24A, 24B, 25A, 25B, and 25C,are cross-sectional views of a portion of an NSFET device at various stages of manufacturing, in accordance with another embodiment.

FIGS. 26A, 26B, 27A, 27B, 28A, 28B, and 28C, are cross-sectional views of a portion of an NSFET device at various stages of manufacturing, in accordance with yet another embodiment.

FIG. 29 illustrates a chemical reaction for forming a passivation layer, in an embodiment.

FIGS. 30A and 30B together illustrate a flow chart of a method of forming a semiconductor device, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

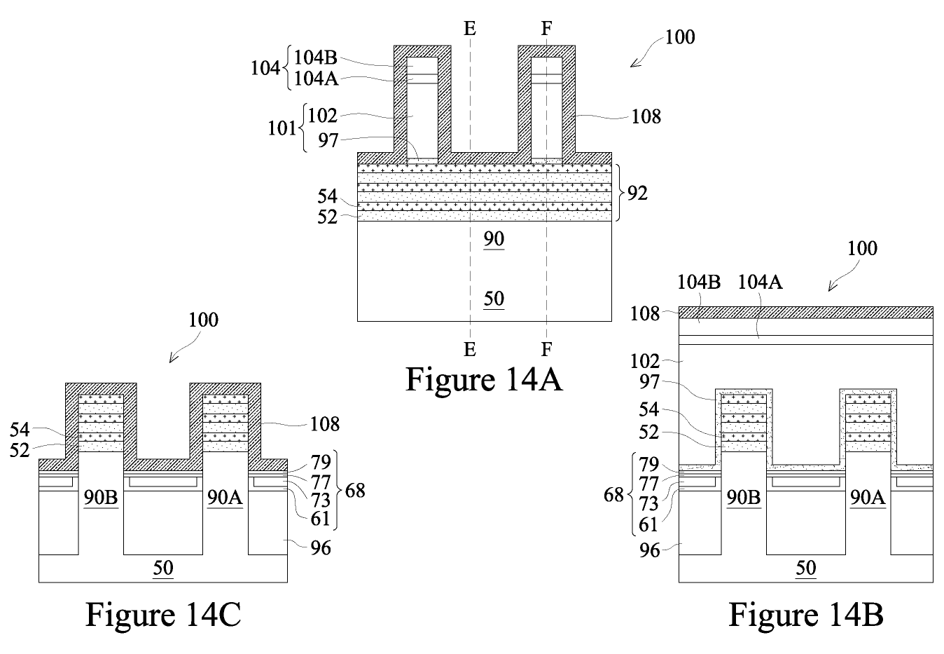

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise specified, the same or similar reference numeral in different figures refer to the same or similar component formed by a same or similar formation process using a same or similar material(s). In addition, figures with the same numeral but different alphabets (e.g., FIGS. 14A – 14C) illustrate different views of the device at the same stage of processing.

Disclosed embodiment relates to a shallow trench isolation (STI) protection structure formed on the STI regions of an NSFET device. The STI protection structure protects the STI regions (e.g., portions directly under dummy gate structure) during the selective etching of a disposable material used in a disposable oxide interposer (DOI) process for forming the NSFET device. In some embodiments, a fin structure is formed protruding above a substrate and above STI regions on opposing sides of the fin structure. The fin structure includes a fin and a layer stack over the fin, where the layer stack comprises alternating layers of a first semiconductor material and a second semiconductor material. Next, an STI protection structure is formed on the upper surfaces of the STI regions using area-selective atomic layer deposition (AS-ALD). In some embodiments, the STI protection structure comprises a liner layer, a hard mask layer over the liner layer, and one or more capping layers over the hard mask layer. In another embodiment, the STI protection structure comprises a single layer of material selectively formed on the upper surfaces of the STI regions 96. Next, a dummy gate structure is formed over the fin structure, and source/drain openings are formed on opposing sides of the dummy gate structure. Next, the first semiconductor material in the layer stack and under the dummy gate structure is replaced by a sacrificial material. Source/drain regions are formed next in the source/drain openings. Next, the dummy gate structure is replaced by a replacement gate structure in a replacement gate process. During the selective etching process used for removing the sacrificial material to release the second semiconductor material to form the nanostructures, the STI protection structure protects portions of the STI regions disposed directly under the dummy gate structure from the selective etching process, and therefore, prevents or reduces loss of the STI regions due to the selective etching process. Advantages of using the STI protection structure include reduced parasitic capacitance of the replacement gate structure, improved device performance, and improved production yield.

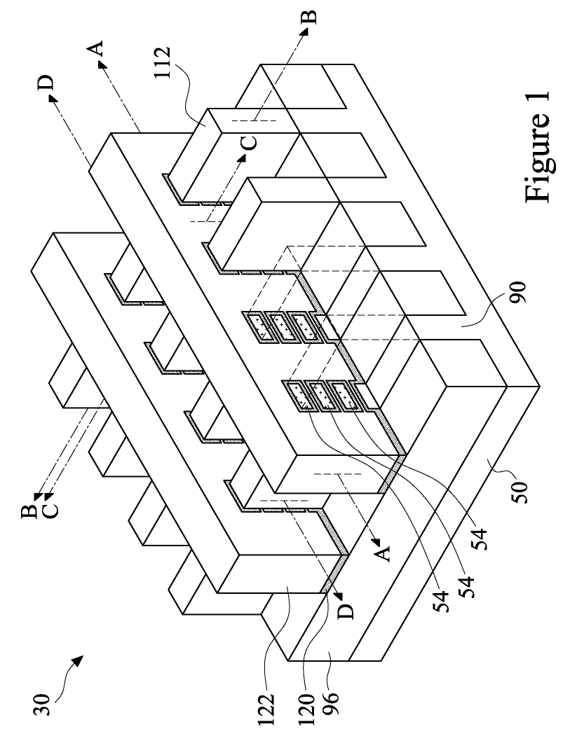

FIG. 1 illustrates an example of a nanostructure field-effect transistor (NSFET) device 30 in a three-dimensional view, in accordance with some embodiments. The NSFET device 30 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between source/drain regions 112. Isolation regions 96 (e.g., shallow trench isolation regions (STI regions)) are formed on opposing sides of the fins 90. A gate dielectric layer 120 is formed around the nanostructures 54. Gate electrodes 122 are over and around the gate dielectric layer 120.

FIG. 1 further illustrates reference cross-sections that are used in later figures. Cross-section A-A is along a longitudinal axis of the gate electrode 122 and in a direction, for example, perpendicular to the direction of current flow between the source/drain regions 112 of the NSFET device 30. Cross-section B-B is perpendicular to cross-section A-A and is along a longitudinal axis of the fin 90 and in a direction of, for example, a current flow between the source/drain regions 112 of the NSFET device. Cross-section C-C is parallel to cross-section B-B and between two neighboring fins 90. Cross-section D-D is parallel to cross-section A-A and extends through source/drain regions 112 of the NSFET device. Subsequent figures may refer to these reference cross-sections for clarity. Note that the NSFET device 30 in FIG. 1 does not illustrate the STI protection structure disclosed herein, and is used mainly to illustrate the locations of the various cross-sections of the NSFET device.

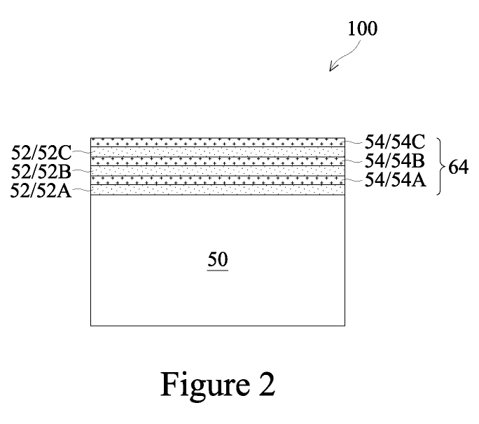

FIGS. 2, 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 14C, 15A, 15B, 15C, 16A, 16B, 16C, 17A, 17B, 17C, 18A, 18B, 18C, 19A, 19B, 19C, 20A, 20B, 20C, 21A, 21B, 22A, 22B, 23A, and 23B,are cross-sectional views of a portion of a nanostructure field-effect transistor (NSFET) device 100 at various stages of manufacturing, in accordance with an embodiment.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, and 52C, and layers formed by the second semiconductor material 54 are labeled as 54A, 54B, and 54C. The number of layers formed by the first and the semiconductor materials illustrated in FIG. 2 are merely non-limiting examples. Other numbers of layers are also possible and are fully intended to be included within the scope of the present disclosure.

In some embodiments, the first semiconductor material 52 is a first type of epitaxial material, such as silicon germanium (SiₓGe₁₋ₓ, where x can be in the range of 0 to 1), and the second semiconductor material 54 is a second type of epitaxial material, such as silicon. The multi-layer stack 64 (which may also be referred to as an epitaxial material stack) will be patterned to form channel regions of an NSFET in subsequent processing. In particular, the multi-layer stack 64 will be patterned and etched to form nanostructures (e.g., nanosheets or nanowires), with the channel regions of the resulting NSFET including multiple horizontally extending nanostructures.

The multi-layer stack 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material (e.g., silicon germanium), and the second set of precursors includes precursors for the second semiconductor material (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 52; and (2) disabling the flow of the germanium precursor to the growth chamber when growing the second semiconductor material 54. The cyclical exposure may be repeated until a target number of layers is formed.

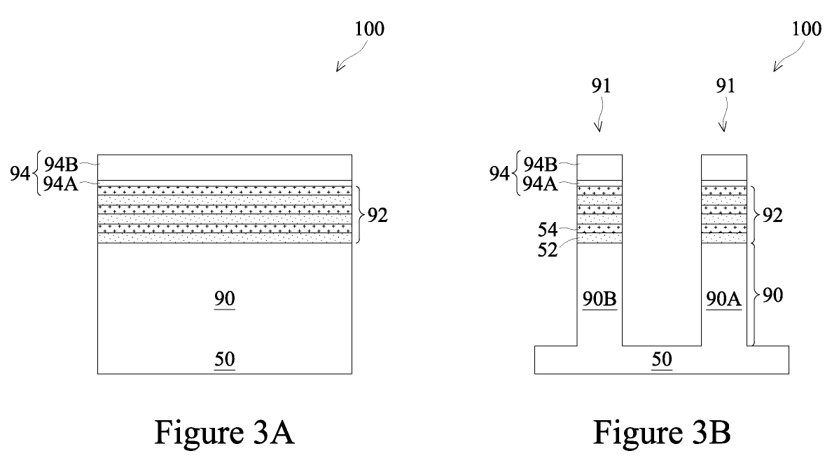

FIGS. 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 14C, 15A, 15B, 15C, 16A, 16B, 16C, 17A, 17B, 17C, 18A, 18B, 18C, 19A, 19B, 19C, 20A, 20B, 20C, 21A, 21B, 22A, 22B, 23A. and 23B, are cross-sectional views of the NSFET device 100 at subsequent stages of manufacturing, in accordance with an embodiment. FIGS. 3A, 4A, 5A, 6A, 7A, 8A, 9A, 10A, 11A, 12A, 13A, 14A, 15A, 16A, 17A, 18A, 19A, 20A, 21A, 22A, and 23A, are cross-sectional views along cross-section B-B in FIG. 1. FIGS. 3B, 4B, 5B, 6B, 7B, 8B, 9B, 10B, 11B, 12B, 13B, 14B, 15B, 16B, 17B, 18B, 19B, 20B, 21B, 22B, and 23B, are cross-sectional views along cross-section A-A in FIG. 1. FIGS. 14C, 15C, 16C, 17C, 18C, 19C, and 20C, are cross-sectional views along cross-section D-D in FIG. 1. The number of fins and the number of gate structures illustrated in the figures are merely non-limiting examples, it should be appreciated that other numbers of fins and other numbers of gate structures may also be formed.

In FIG. 3A and 3B, fin structures 91 are formed protruding above the substrate 50. Each of the fin structures 91 includes a semiconductor fin 90 (also referred to as a fin 90) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etching process, such as a reactive ion etch (RIE), neutral beam etch (NBE), the like, or a combination thereof. The etching is an anisotropic etching process, in some embodiments. After the etching process, the patterned multi-layer stack 64 forms the layer stacks 92, and the patterned portion of the substrate 50 forms the fins 90 (e.g., 90A or 90B), as illustrated in FIG. 3A and 3B. The remaining (e.g., un-patterned) portion of the substrate 50 is referred to as the substrate 50 in FIGS. 3A and 3B and subsequent figures. Therefore, in the illustrated embodiment, the layer stack 92 also includes alternating layers of the first semiconductor material 52 and the second semiconductor material 54. The fin 90 is formed of a same material as the substrate 50. In the example of FIGS. 3A and 3B, fins 90A and 90B are formed to extend parallel to each other.

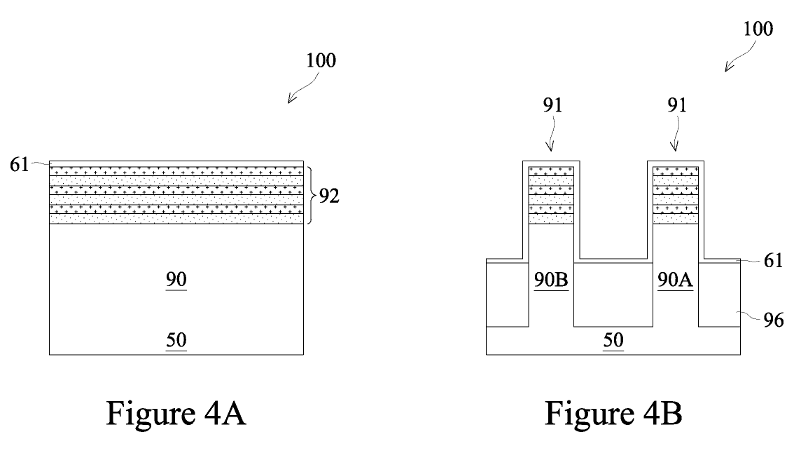

Next, in FIGS. 4A and 4B, shallow trench isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material disposed over the fin structures 91. In some embodiments, a planarization process such as a chemical mechanical polish (CMP), an etch back process, combinations thereof, or the like, may be utilized. The planarization process exposes the layer stacks 92 such that top surfaces of the layer stacks 92 and the insulation material are level after the planarization process is complete. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than other materials). For example, a chemical oxide removal with a suitable etchant such as dilute hydrofluoric (dHF) acid may be used.

Still referring to FIGS. 4A and 4B, a liner layer 61 is formed over exterior surfaces of the fin structures 91 and over the upper surfaces of the STI regions 96. Here, the exterior surfaces of the fin structures 91 refer to the surfaces of the portions of the fin structures 91 extending above the STI regions 96, in the illustrated embodiment. The liner layer 61 may be a suitable dielectric material such as silicon oxide, and may be formed using a suitable deposition method such as CVD, atomic layer deposition (ALD), or the like. The liner layer 61 protects the layer stacks 92 from damage by subsequent etching process(es) used to form an STI protection structure 68, in some embodiments. The liner layer 61 may also be referred to as an oxide liner layer. Besides silicon oxide, other suitable material, such as a dielectric material that provides high etching selectivity from the layer stack 92 and the subsequently formed hard mask layer 73 may also be used. In the illustrated embodiments, the liner layer 61 has a substantially uniform thickness. For example, the horizontal portions of the liner layer 61 (e.g., portions along the top surfaces of the fin structures 91 or along the upper surfaces of the STI regions 96) has a first thickness, the vertical portions of the liner layer 61 (e.g., portions along the sidewalls of the fin structures 91) has a second thickness, and the first thickness is within about 10% (e.g., between 90% and 110%, or between 95% and 105%) of the second thickness. The liner layer 61 may have a thickness (e.g., an average thickness) between about 2 nm and about 4 nm, such as 3 nm, as an example.

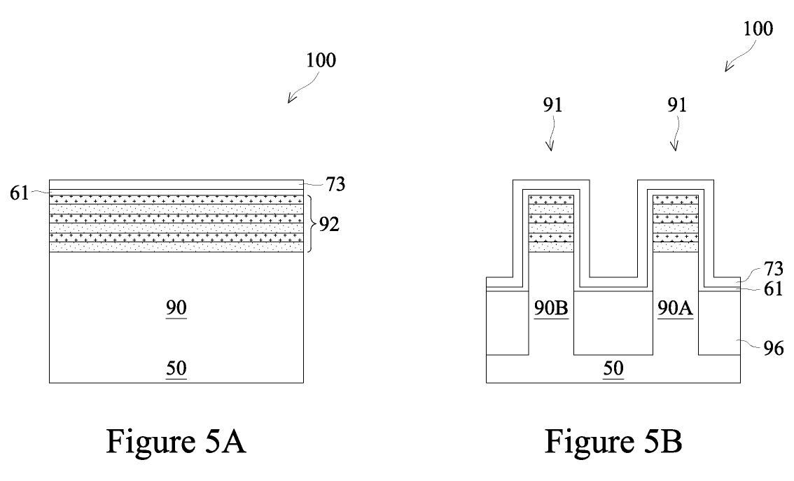

Next, in FIGS. 5A and 5B, a hard mask layer 73 is formed over the liner layer 61. The hard mask layer 73 is formed of a material different from the liner layer 61 and the STI regions 96. In some embodiments, the material of the hard mask layer 73 is chosen to provide high etching selectivity from the material of the STI regions 96, such that in a subsequent sheet formation process (e.g., an etching process) to form nanostructures (e.g., nanosheets), the hard mask layer 73 protects the STI regions 96 to prevent loss of the STI regions 96. In an embodiment, the STI regions 96 is formed of silicon oxide, and the hard mask layer 73 is formed of silicon nitride. Besides silicon nitride, other suitable materials, such as silicon oxynitride, silicon oxycarbonitride, or the like, may also be used for the hard mask layer 73. A suitable formation method, such as CVD, plasm-enhanced CVD (PECVD), or the like, may be used to form the hard mask layer 73. A thickness (e.g., average thickness) of the hard mask layer 73 may be between about 5 nm and about 12 nm, such as 6 nm, 10 nm, as examples. In some embodiments, the hard mask layer 73 has a substantially uniform thickness. For example, a thickness of the horizontal portions of the hard mask layer 73 is within about 10% (e.g., between 90% and 110%, or between 95% and 105%) of a thickness of the vertical portions of the hard mask layer 73. In some embodiments, the horizontal portions of the hard mask layer 73 are formed to be thicker than (e.g., between about 1.5 times and about 3 times, such as between about twice and about three times) the vertical portions of the hard mask layer 73.

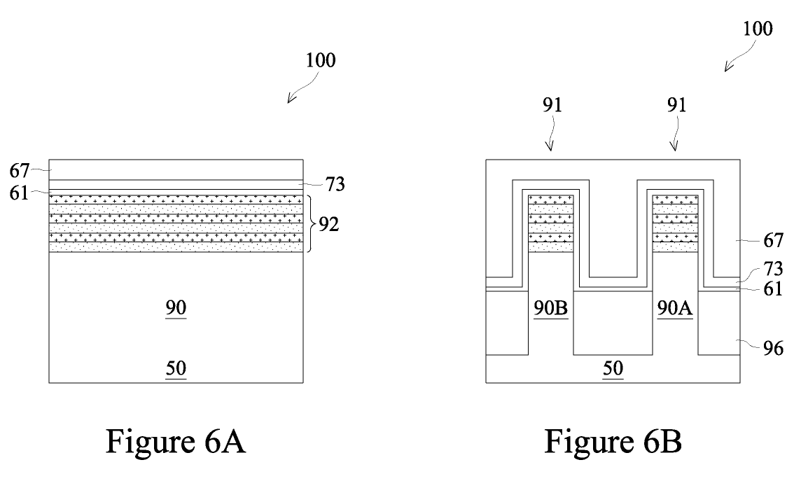

Next, in FIGS. 6A and 6B, a mask layer 67 is formed over the hard mask layer 73. In some embodiments, the mask layer 67 is a Bottom Anti-Reflective Coating (BARC) layer typically used in a tri-layered photoresist. The BARC layer may be a carbon-containing material, such as spin-on glass (SOG) carbon, as an example. Therefore, the mask layer 67 may also be referred to as a BARC layer 67 in the discussion herein, with the understanding that besides the BARC layer, other suitable materials may also be used. As illustrated in FIGS. 6A and 6B, the BARC layer 67 fills the trenches between adjacent fin structures 91, and covers the top surfaces of the fin structures 91.

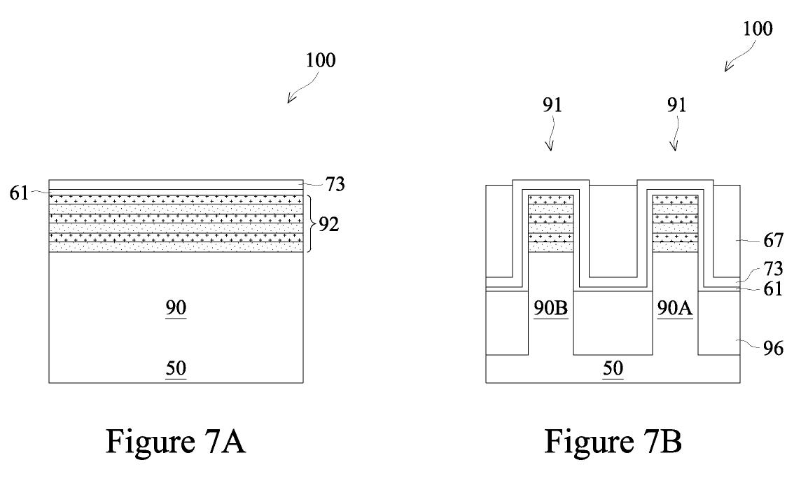

Next, in FIGS. 7A and 7B, the BARC layer 67 is etched back to expose the top portions of the hard mask layer 73 disposed on the top surfaces of the fin structures 91. A suitable etching process, such as a dry etching process, a wet etching process, combinations thereof, or the like, may be performed to etch back the BARC layer 67. The etching process may be a timed process to etch back the BARC layer 67 by a pre-determined amount. In some embodiments, the etching process is performed using an etchant selective to (e.g., having a higher etching rate for) the material of the BARC layer 67, such that the BARC layer 67 is removed without substantially attacking the hard mask layer 73.

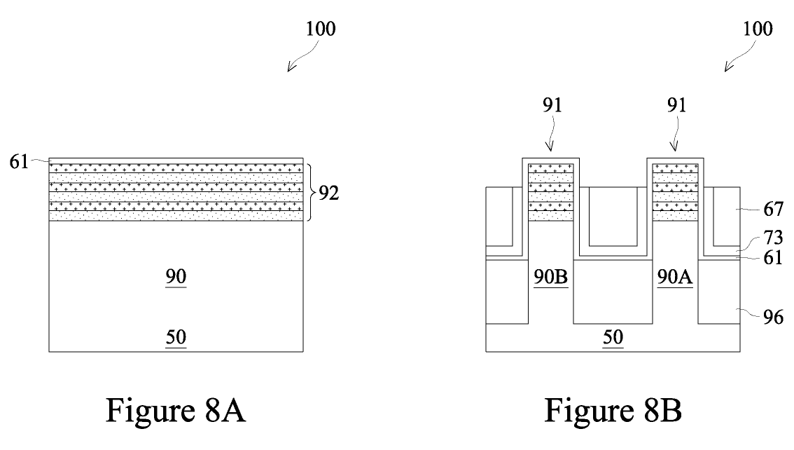

Next, in FIGS. 8A and 8B, the exposed top portions of the hard mask layer 73 are removed by an etching process. For example, a dry etching process using, e.g., a gas source comprising a fluorine-based etching gas, may be performed to remove the exposed top portions of the hard mask layer 73. The gas source may include NF₃ and H₂, as an example. As another example, a wet etching process using, e.g., phosphoric acid (H₃PO₄), may be performed to remove the exposed top portions of the hard mask layer 73. In the illustrated example of FIGS. 8A and 8B, the etching process also recesses the BARC layer 67 and removes upper sidewall portions of the hard mask layer 73. Due to the etching selectivity between the liner layer 61 and the BARC layer 67/the hard mask layer 73, the liner layer 61 remains substantially un-etched, and still covers the sidewalls of the fin structures 91 and the top surfaces of the fin structures 91. Therefore, the liner layer 61 protects the layer stacks 92 (and subsequently formed nanostructures 54) from damage caused by the etching processes used for forming the STI protection structure 68.

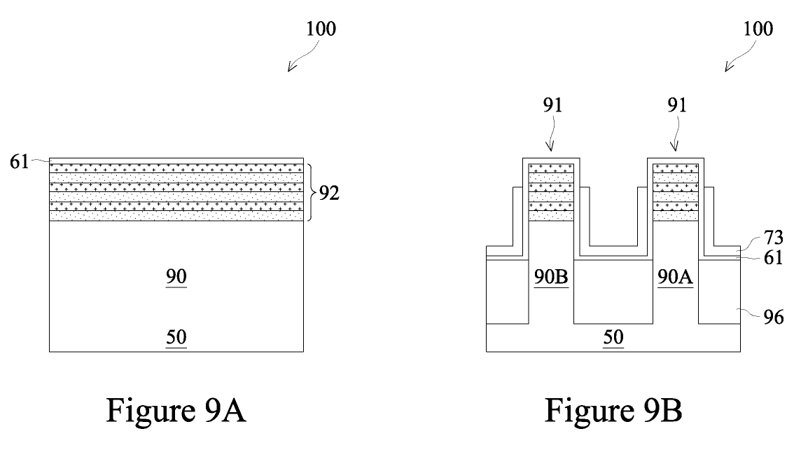

Next, in FIGS. 9A and 9B, the remaining portions of the BARC layer 67 are removed by an etching process. The etching process may be dry etching, wet etching, combinations thereof, or the like. In some embodiments, the etching process is a plasma etching process performed using a gas source comprising H₂ and N₂ gases. After the removal of the remaining portions of the BARC layer 67, remaining portions of the hard mask layer 73 are exposed. The remaining portions of the hard mask layer 73 include sidewall portions along the sidewalls of the fin structures 91, and include bottom portions along the upper surfaces of the STI region 96.

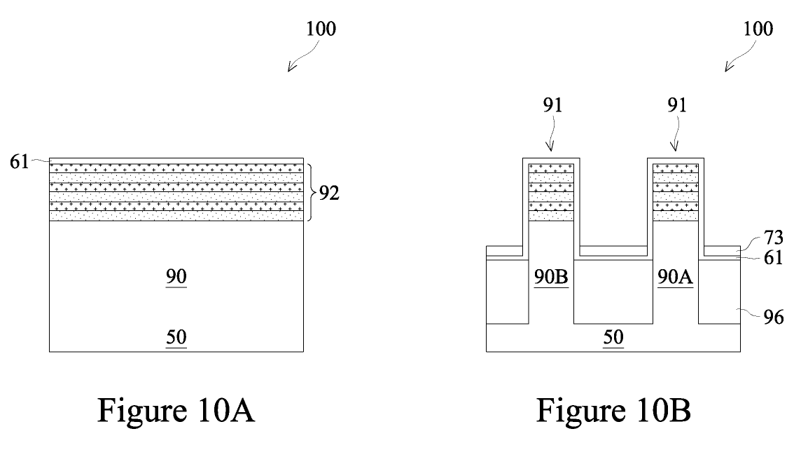

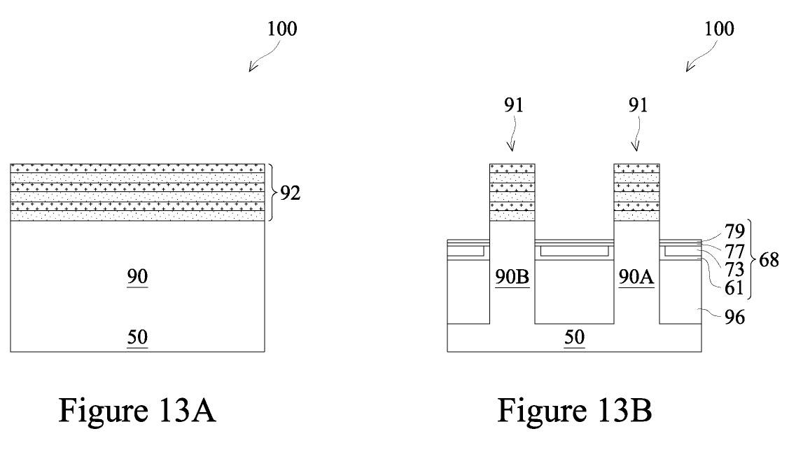

Next, in FIGS. 10A and 10B, the sidewall portions of the hard mask layer 73 are removed by an etching process. The etching process may be a dry etching process, a wet etching process, combinations thereof, or the like. In some embodiments, a dry etching process is performed to remove the sidewall portions of the hard mask layer 73 using a fluorine-based etching gas, such as HF, NF₃, or combinations thereof. The processing condition of the dry etching process may be tuned to achieve a lateral etch rate that is higher than a vertical etch rate, such that the sidewall portions of the hard mask layer 73 are removed at a faster rate than the bottom portions of the hard mask layer 73. In some embodiments, a wet etching process is performed to remove the sidewall portions of the hard mask layer 73. In an embodiment, the wet etching process is performed by etching using a first etchant (e.g., H₃PO₄) for a first duration of time, then etching using a second etchant (e.g., SC1, which is a mixture of deionized water, ammonia water, and hydrogen peroxide) for a second duration of time. Note that the wet etching process may be isotropic, and therefore, may be suitable for embodiments where the hard mask layer 73 has a non-uniform thickness. For example, the thicker bottom portions (e.g., horizontal portions at the bottoms of the trenches between the fin structures 91) of the hard mask layer 73 ensure that after the wet etching process to remove the sidewall portions of the hard mask layer 73, the remaining bottom portions of the hard mask layer 73 have enough thickness to properly form the STI protection structure 68 (see, e.g., FIG. 13B).

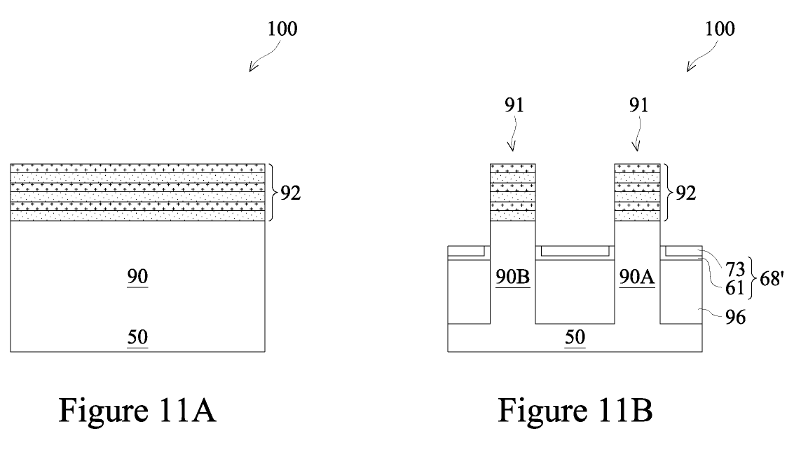

Next, in FIGS. 11A and 11B, portions of the liner layer 61 disposed above the remaining bottom portions of the hard mask layer 73 are removed by an etching process. A suitable etching process, such as dry etching process, wet etching process, combinations thereof, or the like, may be used to remove the portions of the liner layer 61. In an embodiment, the portions of the liner layer 61 is removed by a wet etching process performed using a mixture of HF and SC1. After the etching process, the remaining portions of the liner layer 61 and the remaining portions of the hard mask layer 73 form a STI protection structure 68’. As illustrated in FIGS. 11A and 11B, the STI protection structure 68’ covers (e.g., contacts and extends along) the upper surfaces of the STI regions 96.

In a subsequent sheet formation process (e.g., an etching process), the sacrificial material 57 is selectively removed to release the second semiconductor material 54 to form nanostructures (e.g., nanosheets). Since the sacrificial material 57 and the STI regions 96 may be formed of a same or similar material (e.g., silicon oxide), the etchant used for the sheet formation process may also etch the STI regions 96 and cause loss of the STI regions 96, if the STI regions 96 are not protected (e.g., are exposed to the etchant). The STI protection structure 68’ protects (e.g., shields) the STI regions 96 from the sheet formation process and helps to reduce the loss of the STI regions 96. However, depending on, e.g., the etchant used in the sheet formation process, the STI protection structure 68’ may itself be damaged (e.g., etched) in the sheet formation process, and loss of the STI regions 96 may still occur. In some embodiments of the present disclosure, one or more capping layers (see, e.g., 77 and 79 in FIG. 13B) are formed on the STI protection structure 68’, and the STI protection structure 68’ together with the capping layers form an STI protection structure 68. The STI protection structure 68 is more etch-resistant to the sheet formation process, thus offers enhanced protection for the STI regions 96. Details are discussed hereinafter.

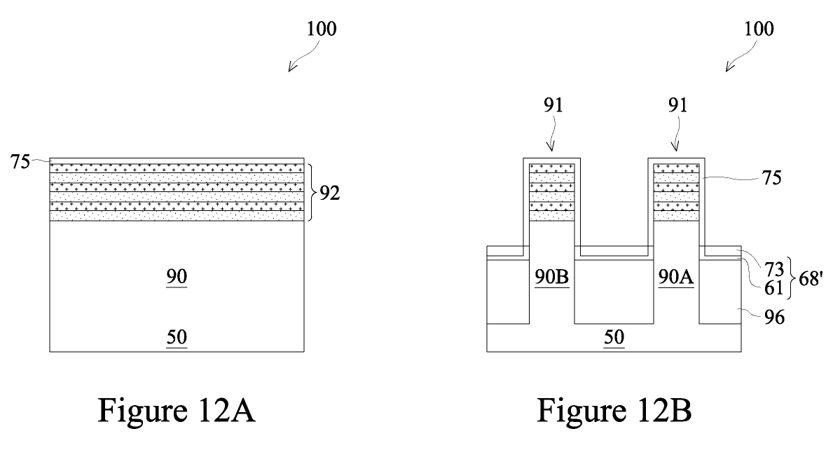

Next, in FIGS. 12A and 12B, a passivation layer 75 is selectively formed over the exterior surfaces of the fin structures 91. Here, the exterior surfaces of the fin structures 91 refer to the surfaces of the portions of the fin structures 91 extending above the STI protection structure 68’. Notably, the passivation layer 75 is not formed over the upper surface of the STI protection structure 68’. The passivation layer 75 hinders formation of the subsequently formed capping layers (see 77, 79 in FIG. 13B), such that the capping layers are selectively formed on the upper surface of the STI protection structures 68’ but not on the exterior surfaces of the fin structures 91.

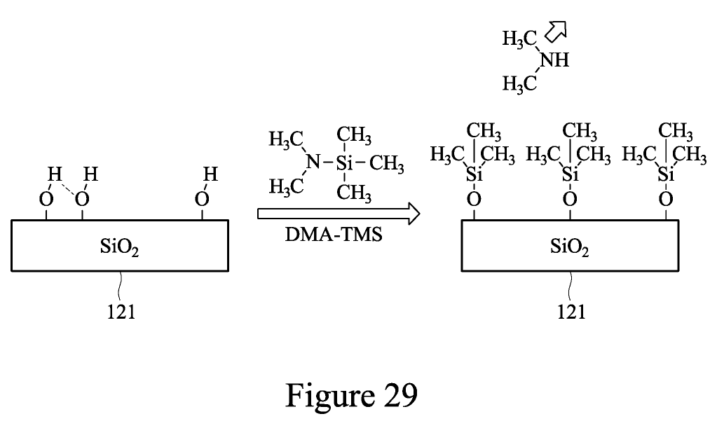

In some embodiments, the passivation layer 75 is formed by a vapor-phase deposition process using dimethylamine-trimethylsilane (DMA-TMS, or (CH₃)₃Si-N(CH₃)₂). For example, DMA-TMS may be introduced in gaseous form at a low temperature, e.g., typically at room temperature or slightly elevated temperatures (up to about 150°C). FIG. 29 shows an example of the chemical reaction that forms the passivation layer 75.

Referring to FIG. 29, a layer 121 of oxide (e.g., silicon oxide) is shown. The layer 121 of oxide may correspond to the native oxide (e.g., oxide formed by chemical reaction with oxygen in the ambient air) formed along the exterior surfaces of the fin structures 91. The surface of oxide typically has hydroxyl (-OH) groups. The DMA-TMS react with these hydroxyl groups on the surface of oxide. The reaction results in the formation of Si-O-Si bonds, with the trimethylsilyl group (-Si(CH₃)₃) attaching to the oxide surface, and the dimethylamine group ((CH₃)₂N-) is released as a byproduct. The chemical reaction may be represented as: SiOH + (CH₃)₃Si-N(CH₃)₂ → Si-O-Si(CH₃)₃ + HN(CH₃)

The above reaction tends to stop once the available surface hydroxyl groups are consumed, and therefore, is self-limiting. A monolayer of trimethylsilyl groups bonded to the oxide surface is formed as a result of the chemical reaction. This monolayer is hydrophobic and can act as a passivation layer or blocking layer. Note that the upper surface of the hard mask layer 73 (e.g., silicon nitride) does not have the hydroxyl groups, and therefore, the passivation layer 75 is not formed on the upper surface of the hard mask layer 73. In other words, the passivation layer 75 is selectively formed along the exterior surfaces of the fin structures 91. The thickness of the passivation layer 75 relative to that of other material (e.g., 61 or 73) shown in FIGS. 12A and 12B may be exaggerated to clearly illustrate the passivation layer 75.

In other embodiments, the passivation layer 75 is formed by treating the exterior surfaces of the fin structures 91 with a plasma process. For example, a plasma process may be performed using a nitrogen-containing gas source, such as a gas source that includes N₂ or NH₃. In some embodiments, the nitrogen plasma modifies the exterior surfaces of the fin structures 91 by breaking the dangling bonds at the exterior surfaces of the fin structures 91 to form a hydrophobic surface layer for the fin structures 91, which hydrophobic surface layer functions as the passivation layer 75. In some embodiments, the gas source of the plasma process further includes H₂ for process control and for fine-tuning various aspects of the plasma process. For example, by adjusting the ratio between N₂ (or NH₃) and H₂, the surface reactivity can be fined-tuned. As another example, hydrogen atoms may terminate the dangling bonds at the exterior surfaces of the fin structures 91 to form Si-H bonds, and the formation of the Si-H bonds contributes to the hydrophobic nature of the treated surface.

Next, in FIGS. 13A and 13B, a capping layer 77 is selectively formed on the upper surface of the STI protection structure 68’, and a capping layer 79 is then selectively formed on the capping layer 77 to form the STI protection structure 68. After the STI protection structure 68 is formed, the passivation layer 75 is removed. The capping layers 77 and 79 may be considered additional hard mask layers, and therefore, the STI protection structure 68 in FIG. 13B may also be referred to as an STI protection structure with a tri-layered hard mask.

In some embodiments, the capping layer 77 is formed of a material such as an aluminum-containing compound, a nitride, or the like. In some embodiments, the capping layer 77 is formed of a metal nitride. In an embodiment, the capping layer 77 is a layer of aluminum nitride (e.g., AlN) formed by an ALD process. In some embodiments, the ALD process is performed using an aluminum-containing precursor, such as trimethylaluminum (TMA, or Al(CH3)3) or aluminum chloride (AlCl3), and using a nitrogen-containing precursor, such as ammonia (NH3) or nitrogen (N2).

The ALD process typically includes a plurality of deposition cycles (also referred to as ALD cycles, or cycles), where each ALD cycle typically includes the following sequentially performed processing steps. Step a): First precursor pulse step, where a first precursor is introduced into the process chamber to react with the underlying surface and form a monolayer. Step b): Purge step, where excess precursor and byproducts from Step a) are purged from the process chamber using an inert gas (e.g., Ar or N₂). Step c): Second precursor pulse step, where a second precursor is introduced into the process chamber to react with the adsorbed monolayer formed in Step a). Step d): Purge step, where excess precursor and byproducts from Step c) are purged from the process chamber using an inert gas. The ALD cycle is repeated multiple times until a target thickness for the layer being formed is reached. In an example ALD process used for forming aluminum nitride (e.g., AlN) as the capping layer 77, the first precursor of the ALD process is an aluminum-containing precursor, such as TMA or AlCl₃, and the second precursor of the ALD process is a nitrogen-containing precursor, such as NH₃ or N₂. The nitrogen-containing precursor may be ignited into a plasma by an RF source during the Step c) of the ALD process, in some embodiments.

Next, the capping layer 79 is selectively formed on the capping layer 77. In some embodiments, the capping layer 79 is a layer of a carbon-containing material, such as silicon carbonitride (e.g., SiCN) formed using an ALD process. The ALD process may be performed using a first precursor that contains silicon and carbon, and a second precursor that contains nitrogen. The first cursor may be tetramethylsilane (TMS, or Si(CH₃)₄), and the second precursor may be NH₃ or N₂, as an example. In some embodiments, the passivation layer 75 hinders formation of SiCN on the passivation layer 75. In addition, the lattice structure of the capping layer 77 (e.g., AlN) is the same as or similar to that of the capping layer 79 (e.g., SiCN), which is conducive for forming the capping layer 79 on the capping layer 77, in some embodiments. For example, the similarity in the lattice structures makes it energetically favorable for SiCN to nucleate and grow on AlN. The lattice similarity may also lead to better adhesion and more coherent interfaces, and may reduce strain and defects at the interface between the two materials. In some embodiments, the lattice similarity promotes layer-by-layer growth in early stages of deposition, and may lead to more uniform and controlled film formation. Therefore, the lattice similarity between AlN and SiCN provides a favorable foundation for selective growth of the capping layer 79 on the capping layer 77. A total thickness of the hard mask layer 73 and the capping layers 77 and 79 may be between about 5 nm and about 15 nm, as an example.

Note that due to the blocking effect of the passivation layer 75, and the lattice similarity induced selective growth, the capping layers 77 and 79 are selectively formed in certain areas, such as on the upper surfaces of the hard mask layer 73 and the liner layer 61. The sidewalls and the top surfaces of portions of the fin structures 91 that protrude above the STI protection structure 68 are exposed (e.g., not covered) by the capping layers 77 and 79. Therefore, the ALD processes used for forming the capping layers 77 and 79 are area-selective ALD (AS-ALD) processes.

Advantages are achieved by using AS-ALD processes for forming the capping layers 77 and 79. For example, since the capping layer 77 and 79 are selectively formed on the hard mask layer 73 and not formed along the sidewalls and the top surfaces of the upper portions of the fin structures 91, no etching process is needed after the capping layers 77 and 79 are formed. This is in contrast with the formation of the liner layer 61 and the hard mask layer 73, where a plurality of subsequent etching processes are performed to remove the liner layer 61 and the hard mask layer 73, in order to expose the sidewalls and the top surfaces of the upper portions of the fin structures 91. The AS-ALD processes obviate the need for the plurality of etching processes, and reduce processing time and cost, and increase production throughput.

The STI protection structure 68 with the tri-layered hard mask provides enhanced protection for the STI regions 96 in the subsequent sheet formation process, and as a result, the loss of STI regions during the sheet formation process is prevented or reduced. In addition, the dielectric constants of the capping layers 77 and 79 (e.g., AlN, SiCN) formed in the present disclosure are lower than that of the hard mask layer 73 (e.g. SiN), and therefore, when compared with a reference design where the capping layers 77 and 79 are replaced with a layer of SiN with a thickness equal to a total thickness of the capping layers 77 and 79, the disclosed STI protection structure 68 advantageously reduces the overall dielectric constant (e.g., average dielectric constant) of the STI protection structure 68 and reduces the resistive-capacitive (RC) delay of the device formed. Furthermore, the capping layers 77 and 79 (e.g., AlN, SiCN) are more etch-resistant to the etchant (e.g., dHF) used in the sheet formation process than the hard mask layer 73 (e.g., SiN), thus providing excellent protection for the hard mask layer 73 and the STI regions 96 during the sheet formation process. For example, if the STI protection structure 68’ (see, e.g., FIG. 11B) (instead of the STI protection structure 68) is used in the NSFET device 100 to protect the STI regions 96 (e.g., portions directly under the dummy gate structure), the STI regions 96 may still be removed (e.g., etched) at an etch rate between about 10 nm/minute to about 20 nm/minute when dilute hydrofluoric (dHF) acid is used in the sheet formation process, due to the STI protection structure 68’ being damaged (e.g., etched) by the etchant (e.g., dHF). In contrast, the etch rate of SiCN in dilute hydrofluoric acid is almost zero, which provides excellent protection for the hard mask layer 73 and the liner layer 61, which in turn protects the underlying STI regions 96 from the sheet formation process.

While aluminum nitride (AlN) and silicon carbonitride (SiCN) are used for the capping layers 77 and 79, respectively, in the example discussed above, other suitable materials may also be used for the capping layers 77 and 79. For example, aluminum oxynitride (AlON) and silicon oxycarbonitride (SiOCN) may be used for the capping layers 77 and 79, respectively. The layer of AlON (or SiOCN) may be formed by forming a layer of AlN (or SiCN) first, then oxidizing the layer of material through an oxidization process. The oxidization process may be a thermal oxidization process performed by heating the layer of material (e.g., AlN or SiCN) in an oxygen-containing atmosphere (e.g., air or pure oxygen) at a high temperature (e.g., between about 800 °C and about 1200 °C), as an example. As another example, the oxidization process may be a plasma process (e.g., an implantation process) performed using oxygen ions.

After the capping layers 77 and 79 are formed, the passivation layer 75 is removed using a suitable method. In some embodiments, a thermal process is performed to remove the passivation layer 75. For example, heating the passivation layer 75 to a high temperature (e.g., 400°C or higher) in an oxygen-containing atmosphere breaks the Si-O-Si bonds formed during formation of the passivation layer 75, thus removing the passivation layer 75. As another example, a plasma process may be performed to remove the passivation layer 75 using ions of fluoride.

Next, in FIGS. 14A-14C, a dummy dielectric layer 97 is formed over the STI protection structure 68 and over the sidewalls and the top surfaces of the fin structure 91. The dummy dielectric layer 97 may be, for example, silicon oxide, silicon nitride, a combination thereof, or the like, and may be deposited or thermally grown according to acceptable techniques. In an embodiment, a layer of silicon is conformally formed over the fin structures 91 and over the upper surface of the STI protection structure 68, and a thermal oxidization process is performed to convert the deposited silicon layer into an oxide layer as the dummy dielectric layer 97.

Next, dummy gates 102 are formed over the fin structures 91. To form the dummy gates 102, a dummy gate layer may be formed over the dummy dielectric layer 97. The dummy gate layer may be deposited over the dummy dielectric layer 97 and then planarized, such as by a CMP. The dummy gate layer may be formed of a material such as amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other techniques known and used in the art.

Masks 104 are then formed over the dummy gate layer 102. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectric 97. The dummy gate dielectric 97 and the overlying dummy gate 102 are collectively referred to as a dummy gate structure 101. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91.

Next, a gate spacer layer 108 is formed by conformally depositing an insulating material over the layer stacks 92, the STI protection structure 68, and the dummy gate structures 101. The insulating material may be silicon nitride, silicon carbonitride, a combination thereof, or the like. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

FIGS. 14B and 14C illustrate cross-sectional views of the NSFET device 100 in FIG. 14A along cross-sections F-F and E-E in FIG. 14A, respectively. The cross-sections E-E and F-F correspond to cross-sections D-D and A-A in FIG. 1, respectively. Note that FIGS. 14A illustrates the cross-sectional view along the longitudinal direction (e.g., a current flow direction) of one of the fins 90, the cross-sectional views along the longitudinal directions of other fins 90 are the same or similar unless otherwise specified. In addition, FIG. 14A illustrates two dummy gate structures 101 as a non-limiting example, the number of dummy gate structures 101 over the fins 90 may be any suitable number.

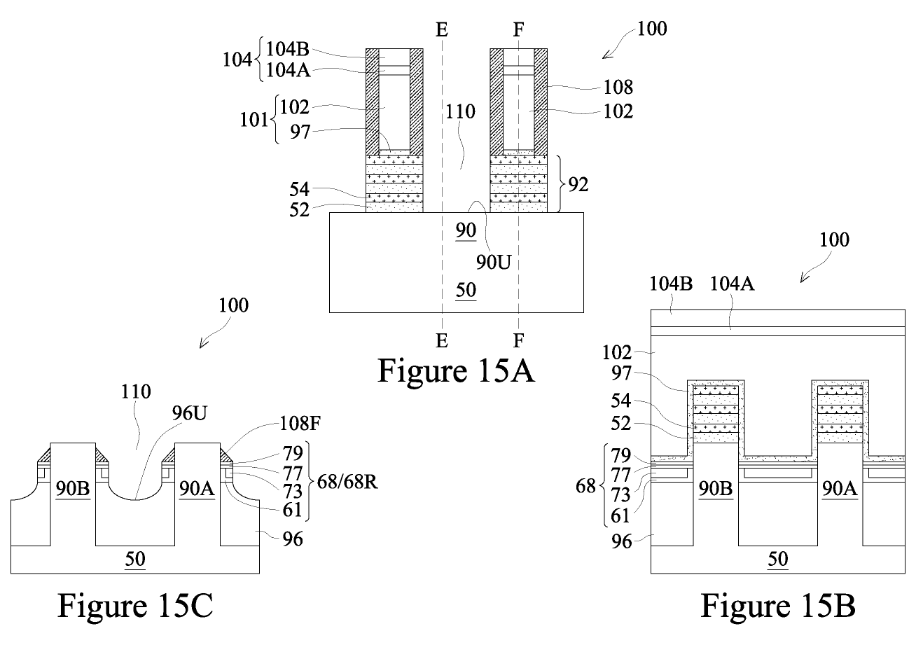

Next, in FIGS. 15A-15C, the gate spacer layers 108 are etched by an anisotropic etching process to form gate spacers 108. The anisotropic etching process may remove horizontal portions of the gate spacer layer 108 (e.g., portions over the STI regions 96 and the dummy gates 102), with remaining vertical portions of the gate spacer layer 108 along sidewalls of the dummy gate structures 101 forming the gate spacers 108. In addition, the remaining vertical portions of the gate spacer layer 108 along sidewalls of the fins 90 form fin spacers 108F (see, e.g., FIG. 15C).

After the formation of the gate spacers 108, implantation for lightly doped source/drain (LDD) regions (not shown) may be performed. Appropriate type (e.g., p-type or n-type) impurities may be implanted into the exposed layer stacks 92 and/or semiconductor fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities of from about 10¹⁵ cm⁻³ to about 10¹⁶ cm⁻³. An anneal process may be used to activate the implanted impurities.

Next, openings 110 (which may also be referred to as recesses 110 or source/drain openings 110) are formed in the layer stacks 92. The openings 110 may extend through the layer stacks 92 and into the fins 90. The openings 110 may be formed by an anisotropic etching process using, e.g., the dummy gate structures 101 and the gate spacers 108 as an etching mask. Upper surfaces 90U of the fins 90 are exposed at the bottoms of the openings 110. Sidewalls of the openings 110 expose the first semiconductor material 52 and the second semiconductor material 54.

In the example of FIG. 15C, the anisotropic etching process for forming the source/drain openings 110 removes portions of the STI protection structure 68 that are disposed beyond sidewalls of the fin spacers 108F, and also removes portions of the underlying STI regions 96, thereby resulting in recesses in the STI regions 96. FIG. 15C shows curved (e.g., concave) upper surfaces 96U of the STI regions 96 due to the etching of the STI regions 96. The removed portions of the STI regions 96 in FIG. 15C are beyond boundaries of (e.g., laterally adjacent to) the dummy gate structures 101, and the removal of these portions of the STI regions 96 does not cause performance issues such as increase in the parasitic capacitance of the subsequently formed replacement gate structures. Note that portions of the STI protection structure 68 and the STI regions 96 under (e.g., directly under) the dummy gate structures 101 are shielded from the anisotropic etching process, thus remain intact.

As illustrated in FIG. 15C, portions of the STI protection structure 68 remain under the fin spacers 108F, and are referred to as remaining portions 68R of the STI protection structure 68. The remaining portions 68R of the STI protection structure 68 protect the fins 90 from over-etching by the anisotropic etching process for forming the source/drain openings 110. Without the remaining portions 68R of the STI protection structure 68, over-etching by the anisotropic etching process may expose and/or remove portions of the fins 90 disposed below the fin spacers 108F. The un-intended removal of the portions of the fins 90 by the over-etching may cause the fins 90 to collapse, and/or may cause un-intended growth of epitaxial source/drain material from the un-intendedly exposed portions of the fins 90 during the subsequent source/drain regions formation process. The un-intended growth of epitaxial source/drain material between adjacent fins 90 may cause electrical short between the adjacent source/drain regions, thus causing device failure. The disclosed method herein, by having the remaining portions 68R of the STI protection structure 68, avoids the above over-etching related issues, thereby preventing or reducing the likelyhood of device failure and improving production yield. This illustrate another advantage of the presently disclosure.

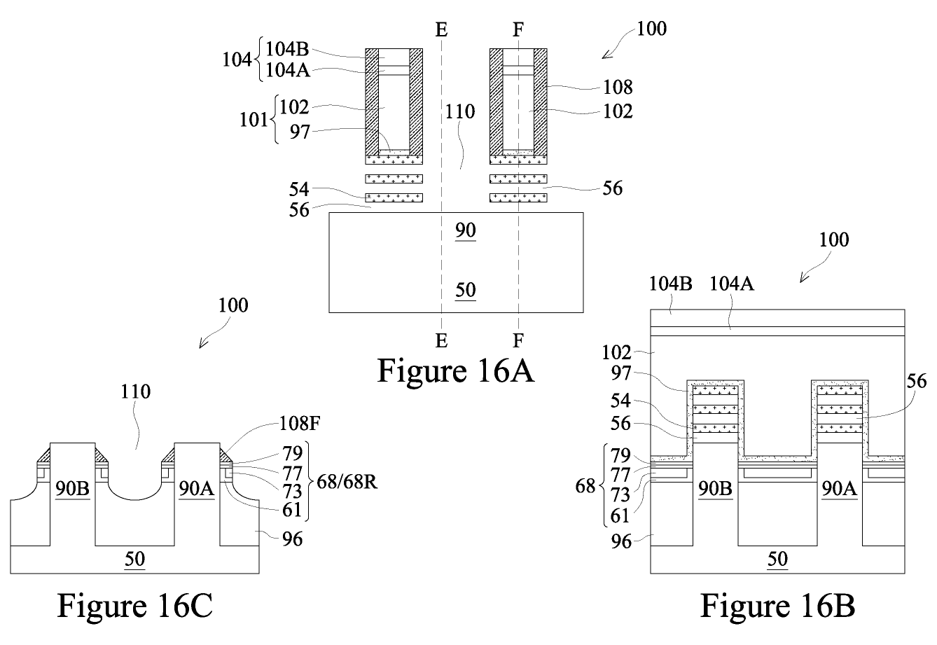

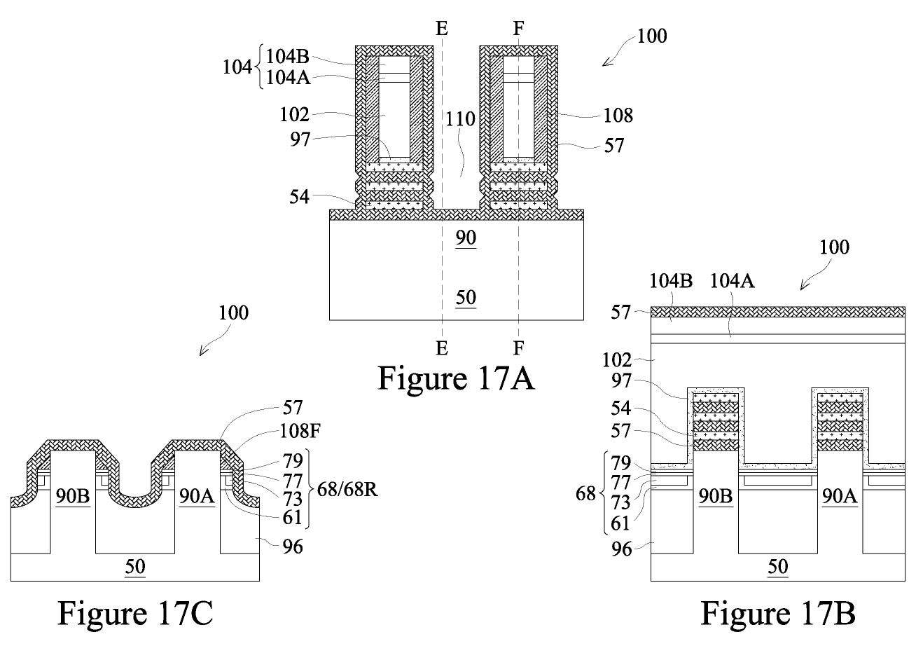

Next, in FIGS. 16A-16C, the first semiconductor material 52 under the dummy gate structures 101 and exposed by the openings 110 are removed. The first semiconductor material 52 may be removed by performing an isotropic etching process such as wet etching or the like using etchant(s) which is selective to the materials of the first semiconductor material 52, while the second semiconductor material 54, the fins 90, the STI regions 96 remain relatively unetched as compared to the first semiconductor material 52. In embodiments in which the first semiconductor material 52 include, e.g., SiGe, and the second semiconductor material 54 include, e.g., Si or SiC, tetramethylammonium hydroxide (TMAH), ammonium hydroxide (NH₄OH), or the like may be used to selectively remove the first semiconductor material 52. After the first semiconductor material 52 is removed, gaps 56 (e.g., empty spaces) are formed between adjacent layers of the second semiconductor material 54, and between the fins 90 and a lowermost layer of the second semiconductor material 54.

Next, in FIGS. 17A-17C, a disposable material 57 (may also be referred to as a sacrificial material 57) is deposited in the openings 110 to line the sidewalls and bottoms of the openings 110. The disposable material 57 also fills the gaps 56. The disposable material 57 may be deposited by a conformal deposition process, such as CVD, ALD, or the like. The disposable material 57 may be a dielectric material. In some embodiments, the disposable material 57 includes one or more layers of silicon oxide (SiO), silicon oxynitride (SiON), aluminum oxide (Al₂O₃), or the like. These materials are selected for their properties, such as etching selectivity, which allows for precise removal during the manufacturing process without adversely affecting the adjacent and underlying structures. The choice of the disposable material 57 may depend on the requirements of the semiconductor device being fabricated and the electrical and physical properties of the final product.

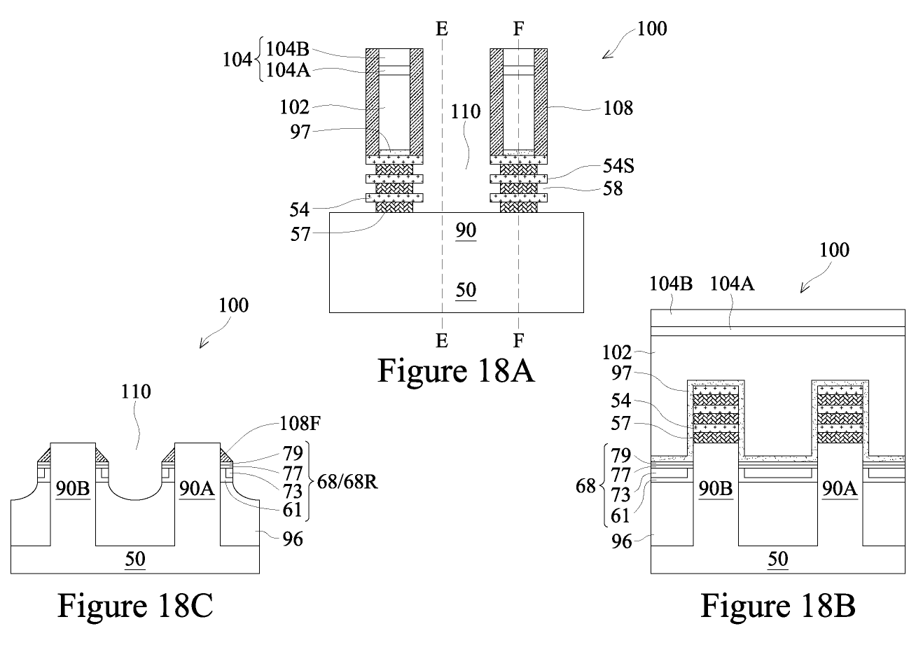

Next, in FIGS. 18A-18C, the disposable material 57 disposed outside the gaps 56 are removed, and sidewalls of the remaining portions of the disposable material 57 are recessed from respective sidewalls 54S of the second semiconductor material 54 to form sidewall recesses 58.

In some embodiments, an anisotropic etching process, e.g. a dry etching process such as a plasma etching process, is performed to remove the disposable material 57 disposed outside the gaps 56. Next, an isotropic etching process, such as a wet etching process, is performed to recess the remaining portions of the disposable material 57 to form the sidewall recesses 58. The dry etching process and the wet etching process may use etchants selective to the disposable material 57, such that the disposable material 57 is etched without substantially attacking other material(s) and/or structures. In some embodiments, multiple etching cycles, where each etching cycle includes the dry etching process followed by the wet etching process, are performed to remove the disposable material 57 and to form the sidewall recesses 58. The etching cycles are repeated until sidewalls of the disposable material 57 are recessed past sidewalls 54S of the second semiconductor material 54. In some embodiments, the disposable material 57 is etched by a wet etching process using hydrogen fluoride, diluted hydrogen fluoride, another fluorine-based etchant, or the like as an etchant. The wet etching process is performed until sidewalls of the disposable material 57 are recessed past sidewalls 54S of the second semiconductor material 54. The remaining portions of the disposable material 57, which are interposed between layers of the second semiconductor material 54, or between the fins 90 and a lowermost layer of the second semiconductor material 54, may be referred to as disposable oxide interposers (DOIs). In the subsequent sheet formation process, the DOIs are selectively removed to release the layers of the second semiconductor material 54 to form nanostructures 54 (e.g., nanosheets, or nanowires). This process may be referred to as a DOI process.

Replacing the first semiconductor material 52 with the disposable material 57 in the DOI process may provide advantages. To appreciate the advantages, consider a reference manufacturing process where the first semiconductor material 52 is not replaced with the disposable material 57. In subsequent source/drain formation steps, one or more high temperature processes may be performed to, for example, activate the dopants in the source/drain regions. When the first semiconductor material 52 (e.g., SiGe) is exposed to high temperatures, germanium in the first semiconductor material 52 may diffuse into and mix with the second semiconductor material 54 (e.g., Si), which is referred to as intermixing between germanium and silicon. Intermixing may increase roughness at interfaces between the first semiconductor material 52 and the second semiconductor material 54, and may cause manufacturing defects that degrade the performance of the resulting devices. By replacing the first semiconductor material 52 with the disposable material 57 prior to the high temperature processes (e.g., source/drain annealing), intermixing is avoided, and manufacturing defects can be reduced and device performance can be improved. In addition, the material (e.g., SiO) of the DOIs provide excellent etching selectivity (e.g., higher than 10000) from the material (e.g. Si) of the second semiconductor material 54, thus allowing for selective removal of the DOIs in the sheet formation process with little or no damage to the nanostructures 54.

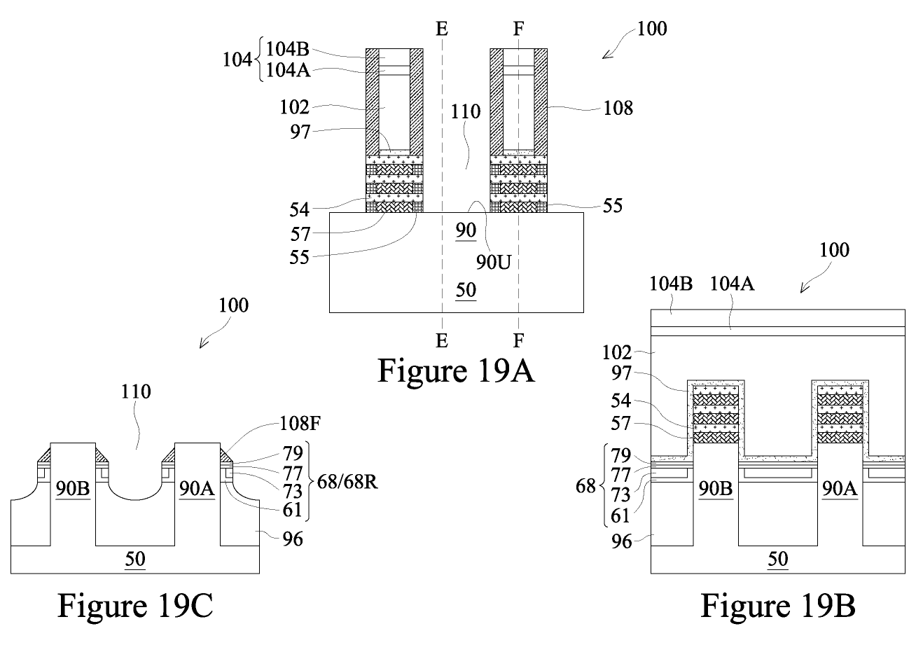

Next, in FIGS. 19A-19C, inner spacers 55 are formed in the sidewall recesses 58. In some embodiments, to form the inner spacers 55, an inner spacer layer is formed (e.g., conformally) in the openings 110. The inner spacer layer also fills the sidewall recesses 58 of the sacrificial material 57. The inner spacer layer may be a suitable dielectric material, such as silicon carbonitride (SiCN), silicon oxycarbonitride (SiOCN), or the like, formed by a suitable deposition method such as PVD, CVD, ALD, or the like. Next, an etching process, such as an anisotropic etching process, is performed to remove portions of the inner spacer layers disposed outside the sidewall recesses 58 of the sacrificial material 57. The remaining portions of the inner spacer layers (e.g., portions disposed inside the sidewall recesses 58 of the sacrificial material 57) form inner spacers 55. As illustrated in FIG. 19A, the openings 110 expose sidewalls of the second semiconductor material 54 and expose upper surfaces 90U of the fins 90.

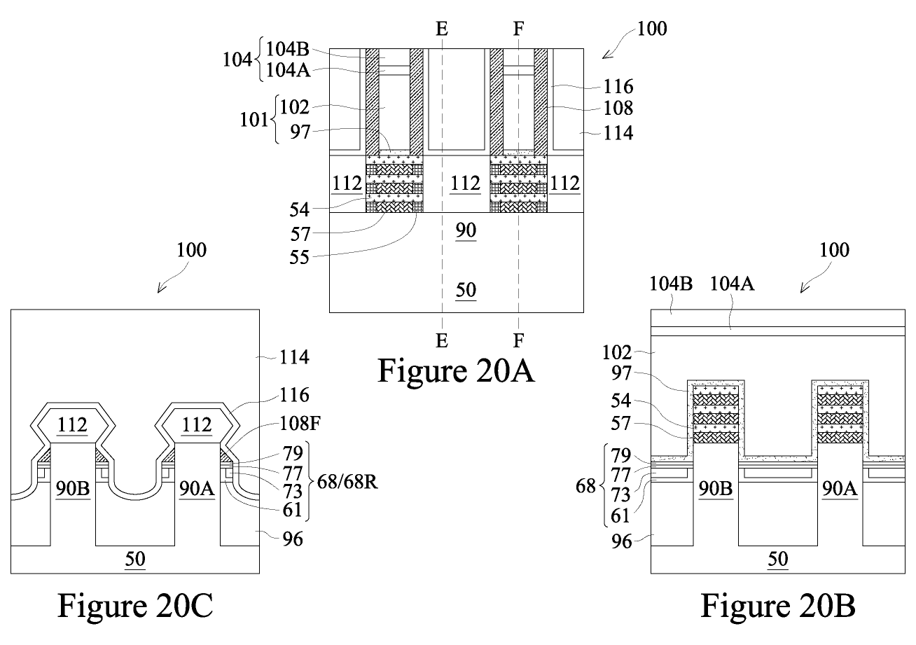

Next, in FIGS. 20A-20C, source/drain regions 112 are formed in the openings 110. In the discussion herein, source/drain region(s) may refer to a source or a drain, individually or collectively dependent upon the context. In the illustrated embodiment, the source/drain regions 112 are formed of an epitaxial material(s), and therefore, may also be referred to as epitaxial source/drain regions 112. In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate structure 101 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed gates of the resulting NSFET device.

The epitaxial source/drain regions 112 are epitaxially grown in the openings 110. The epitaxial source/drain regions 112 may include any acceptable material, such as appropriate for n-type or p-type device. For example, when n-type devices are formed, the epitaxial source/drain regions 112 may include materials exerting a tensile strain in the channel regions, such as silicon, SiC, SiCP, SiP, or the like. Likewise, when p-type devices are formed, the epitaxial source/drain regions 112 may include materials exerting a compressive strain in the channel regions, such as SiGe, SiGeB, Ge, GeSn, or the like. The epitaxial source/drain regions 112 may have surfaces raised from respective surfaces of the fins 90 and may have facets.

The epitaxial source/drain regions 112 and/or the fins 90 may be implanted with dopants to form source/drain regions, similar to the process previously discussed for forming lightly-doped source/drain regions, followed by an anneal. The source/drain regions may have an impurity concentration of between about 10¹⁹ cm⁻³ and about 10²¹ cm⁻³. The n-type and/or p-type impurities for source/drain regions may be any of the impurities previously discussed. In some embodiments, the epitaxial source/drain regions 112 may be in situ doped during growth.

As a result of the epitaxy processes used to form the epitaxial source/drain regions 112, upper surfaces of the epitaxial source/drain regions 112 have facets which expand laterally outward beyond sidewalls of the fins 90. In some embodiments, adjacent epitaxial source/drain regions 112 over adjacent fins 90 remain separated after the epitaxy process is completed, as illustrated in FIG. 20C. In other embodiments, these facets cause adjacent epitaxial source/drain regions 112 to merge.

Next, a contact etch stop layer (CESL) 116 is formed (e.g., conformally) over the source/drain regions 112 and over the dummy gate structures 101, and a first inter-layer dielectric (ILD) 114 is then deposited over the CESL 116. The CESL 116 is formed of a material having a different etch rate than the first ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, PECVD, or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may also be used.

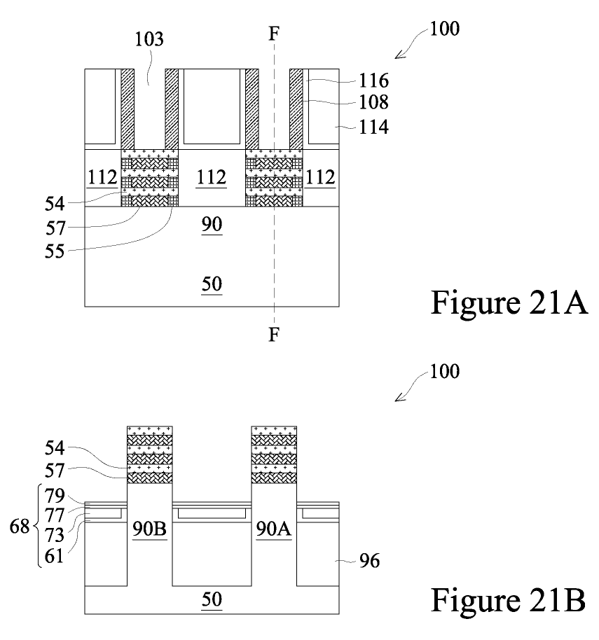

FIGS. 21A, 21B, 22A, 22B, 23A, 23B, illustrate a replacement gate process performed subsequently, where the dummy gate structures 101 are removed and replaced by replacement gate structures 123 (e.g., metal gate structures). The cross-sectional views corresponding to FIG. 20C are not illustrated for the replacement gate process, because such cross-sectional views are the same as FIG. 20C, in some embodiments.

Next, in FIGS. 21A and 21B, the dummy gate structures 101 are removed in an etching step(s), so that recesses 103 (may also be referred to as gate trenches 103) are formed between respective gate spacers 108. In some embodiments, the dummy gates 102 are removed by an anisotropic dry etching process. For example, the etching process may include a dry etching process using reaction gas(es) that selectively etch the dummy gates 102 without etching the first ILD 114 and the gate spacers 108. During the removal of the dummy gates 102, the dummy gate dielectric 97 may be used as an etch stop layer when the dummy gates 102 are etched. The dummy gate dielectric 97 may then be removed after the removal of the dummy gates 102. As illustrated in FIGS. 21A and 21B, each recess 103 exposes underlying channel regions of the NSFET and the STI protection structure 68.

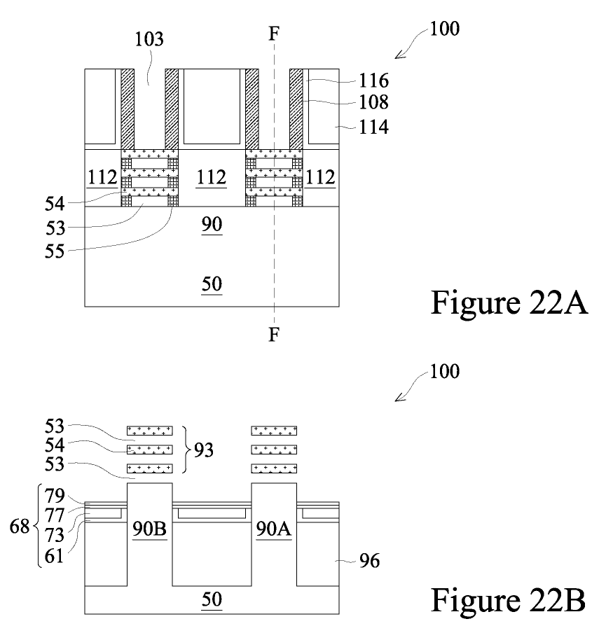

Next, in FIGS. 22A and 22B, the disposable material 57 is removed to release the second semiconductor material 54, which may be referred to as the sheet formation process. After the disposable material 57 is removed, the second semiconductor material 54 (e.g., portions underlying the dummy gates 102 before the dummy gates 102 are removed) forms a plurality of nanostructures 54 that extend horizontally (e.g., parallel to a major upper surface of the substrate 50). The nanostructures 54 may be collectively referred to as the channel regions 93 or the channel layers 93 of the NSFET device 100. As illustrated in FIGS. 22A and 22B, gaps 53 (e.g., empty spaces) are formed between the nanostructures 54 and between the lowermost nanostructure 54 and the fins 90 by the removal of the disposable material 57. In some embodiments, the nanostructures 54 are nanosheets or nanowires, depending on, e.g., the dimensions (e.g., size and/or aspect ratio) of the nanostructures 54.

In some embodiments, the disposable material 57 is removed by a selective etching process using an etchant that is selective to (e.g., having a higher etch rate for) the disposable material 57, such that the disposable material 57 is removed without substantially attacking the second semiconductor material 54. In some embodiments, an isotropic etching process, such as a wet etching process or the like, is performed to remove the disposable material 57. In embodiments where the disposable material 57 include, e.g., SiO₂, and the second semiconductor material 54 include, e.g., Si or SiC, hydrogen fluoride (HF), diluted hydrogen fluoride (dHF), another fluorine-based etchant, or the like, may be used to remove the disposable material 57.

In some embodiments, a high etching selectivity of 10000 or more is achieved between the disposable material 57 and the second semiconductor material 54. In other words, the disposable material 57 is removed by the isotropic etching process at an etching rate 10000 times or more than the etching rate of the second semiconductor material 54. As a result, the etching process (e.g., the sheet formation process) used to remove the disposable material 57 cause little or no damage to the nanostructures 54.

In some embodiments, both the disposable material 57 and the STI regions 96 are formed of an oxide (e.g., silicon oxide). Without the STI protection structure 68, the sheet formation process may remove upper portions of the STI regions 96 disposed under the recesses 103, thus causing recessing of the STI regions 96. The recessing of the STI regions 96 reduces the distance between the subsequent formed replacement gate structure and the substrate. In addition, corner regions of the STI regions 96 (e.g., regions where the upper surfaces of the STI regions 96 contact the sidewalls of the fins 90) may be removed (e.g., etched away) at a faster rate than other regions of the STI regions 96 during the sheet formation process. When the subsequently formed replacement gate structure fills the removed corner regions of the STI regions 96, protrusion of the replacement gate structure occurs. The reduced distance between the replacement gate structure and the substrate, as well as the protrusion of the replacement gate structure, cause an increase in the parasitic capacitance of the replacement gate structure. The present disclosure, by forming the STI protection structure 68, prevents or reduces the likelihood of STI region loss during the sheet formation process, thus reducing the parasitic capacitance of the NSFET device formed and improving the device performance.

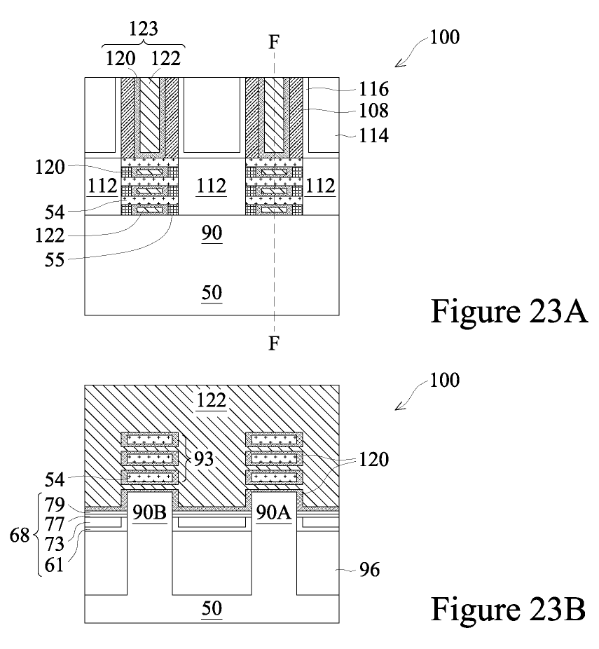

Next, in FIGS. 23A and 23B, gate dielectric layers 120 and gate electrodes 122 are formed to form replacement gate structures 123. In some embodiments, a gate dielectric material 120 is deposited conformally in the recesses 103, such as on the top surfaces and the sidewalls of the fins 90, and on sidewalls of the gate spacers 108. The gate dielectric material 120 may also be formed on the top surface of the first ILD 114. Notably, the gate dielectric material 120 is formed to wrap around the nanostructures 54. In accordance with some embodiments, the gate dielectric material 120 comprises silicon oxide, silicon nitride, or multilayers thereof. In some embodiments, the gate dielectric material 120 comprises a high-k dielectric material, and in these embodiments, the gate dielectric material 120 may have a dielectric constant (e.g., K value) greater than about 7.0, and may include a metal oxide or a silicate of Hf, Al, Zr, La, Mg, Ba, Ti, or Pb, or combinations thereof. The formation methods of the gate dielectric material 120 may include Molecular-Beam Deposition (MBD), ALD, PECVD, and the like.

Next, a gate electrode material 122 is deposited over and around the gate dielectric material 120, and fill the remaining portions of the recesses 103. The gate electrode material may include a metal-containing material such as TiN, TiO, TaN, TaC, Co, Ru, Al, W, combinations thereof, or multi-layers thereof. For example, although a single-layer gate electrode material 122 is illustrated, the gate electrode material 122 may comprise any number of liner layers (e.g., barrier layers), any number of work function tuning layers, and a fill metal material. After the filling of the gate electrode material 122, a planarization process, such as a CMP, may be performed to remove the excess portions of the gate dielectric material 120 and the gate electrode material 122, which excess portions are over the top surface of the first ILD 114. The remaining portions of the gate electrode material 122 and the gate dielectric material 120 thus form the gate electrodes 122 and the gate dielectric layers 120, respectively, of the replacement gate structures 123 of the NSFET device 100. Each gate electrode 122 and the corresponding gate dielectric layer 120 may be collectively referred to as a gate stack 123, a replacement gate structure 123, a metal gate structure 123, or a gate structure 123. Each gate structure 123 extends around the respective nanostructures 54.

Additional processing steps may be performed to complete the fabrication of the NSFET device 100, as skilled artisans readily appreciate. For example, a second ILD may be formed over the first ILD 114. Gate contact plugs and source/drain contact plugs may be formed to extend through the second ILD and/or the first ILD 114 to be electrically coupled to the gate structures 123 and the source/drain regions 112. Next, an interconnect structure, which includes multiple dielectric layers and conductive features (e.g., vias and conductive lines) formed in the multiple dielectric layers, is formed to interconnect the underlying electrical components (e.g., NSFETs) to form functional circuits. Next, external connectors (e.g., copper pillars, conductive bumps) may be formed to be electrically coupled to the interconnect structure to provide electrical connection to external electrical devices. Dicing may be performed to separate multiple NSFET devices 100 formed on a same wafer into separate individual devices. Details are not discussed here.

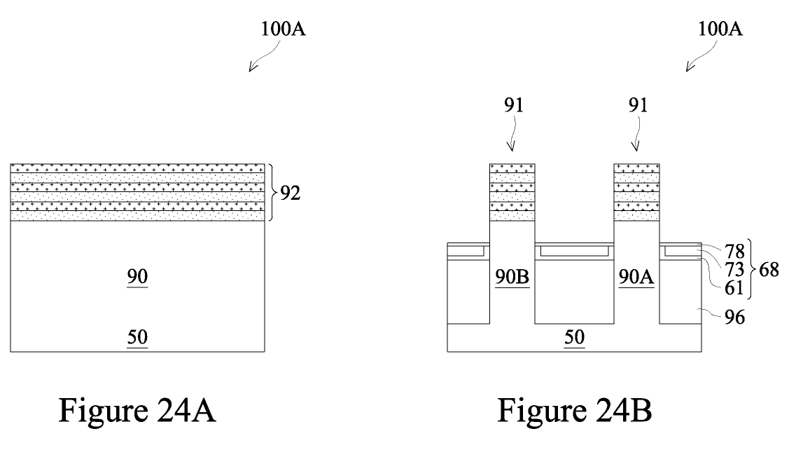

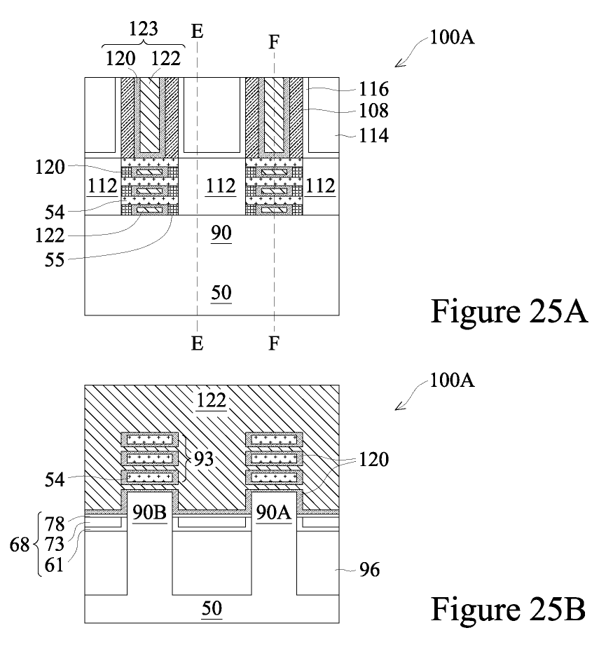

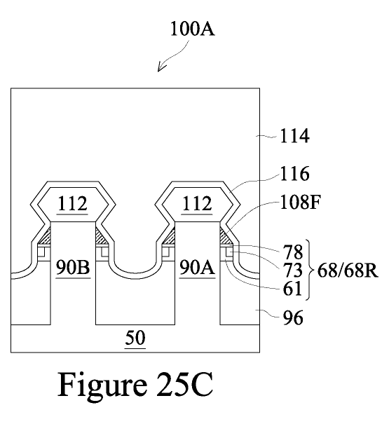

FIGS. 24A, 24B, 25A, 25B, and 25C, are cross-sectional views of a portion of an NSFET device 100A at various stages of manufacturing, in accordance with another embodiment. The NSFET device 100A is similar to the NSFET device 100 and may be formed by similar processing steps, but the STI protection structure 68 of the NSFET device 100A has a different layered structure. Details are discussed hereinafter.

FIGS. 24A and 24B illustrate the NSFET device 100A after formation of a capping layer 78 on the hard mask layer 73 and the liner layer 61. The processing step shown in FIGS. 24A and 24B follows the processing step of FIGS. 12A and 12B. In other words, after the processing steps illustrated in FIGS. 2-12B are performed, the capping layer 78 is selectively formed on the hard mask layer 73 and the liner layer 61 using an AS-ALD process, and the passivation layer 75 (see FIG. 12B) is then removed. The area-selective formation of the capping layer 78 is achieved with the help of the passivation layer 75, details of which are discussed above for the NSFET device 100, thus not repeated here.

In FIGS. 24A and 24B, the capping layer 78, the hard mask layer 73, and the liner layer 61 form the STI protection structure 68 of the NSFET device 100A. The capping layer 78 may be considered a hard mask layer, and therefore, the STI protection structure of FIG. 24B may also be referred to as an STI protection structure with a dual-layered hard mask. After formation of the capping layer 78, the passivation layer 75 is removed, e.g., by a thermal process or a plasma process, same as or similar to those discussed above.

In some embodiments, the capping layer 78 is formed of a dielectric material that is more etch-resistant (e.g., having a lower etch rate) to the sheet formation process and has a lower dielectric constant than the material of the hard mask layer 73. For example, the capping layer 78 may be formed of a carbon-containing material, such as silicon carbonitride (e.g. SiCN), silicon oxycarbonitride (e.g., SiOCN), silicon carbide (e.g., SiC), or silicon oxycarbide (e.g., SiOC), and the hard mask layer 73 may be formed of silicon nitride (e.g., SiN). The material (e.g., SiN) of the hard mask layer 73 is more etch-resistant to the sheet formation process than the material (e.g., SiO) of the liner layer 61, in the illustrated embodiment.

In some embodiments, after the passivation layer 75 (see FIG. 12B) is formed to cover the sidewalls and the top surfaces of upper portions of the fin structures 91, the capping layer 78 is selectively formed on the hard mask layer 73 and the liner layer 61 using an AS-ALD process. In an embodiment where the capping layer 78 is SiCN, the AS-ALD process may be performed using a first precursor that contains silicon and carbon, and a second precursor that contains nitrogen. The first cursor may be tetramethylsilane (TMS, or Si(CH₃)₄), and the second precursor may be NH₃ or N₂, as an example. In some embodiments, the passivation layer 75 hinders formation of SiCN on the passivation layer 75. In addition, the lattice structure of the capping layer 78 (e.g., SiCN) is the same as or similar to that of the hard mask layer 73 (e.g., SiN), which is conducive for forming the capping layer 78 on the hard mask layer 73, in some embodiments. The reasons and advantages of the preferential growth of SiCN on SiN provided by the lattice similarity are the same as or similar to those discussed above for the capping layer 79, thus not repeated here. A total thickness of the capping layers 78 and the hard mask layer 73 may be between about 5 nm and about 15 nm, as an example.

In some embodiments, the capping layer 78 is SiOCN and is formed by: forming a layer of SiCN using the AS-ALD process discussed above, then oxidizing the layer of SiCN into SiOCN, thus forming the capping layer 78. The oxidization process may be, e.g., a thermal oxidization process or a plasma process (e.g., ion implantation). Details are the same as or similar to those discussed above, thus not repeated.

In some embodiments, the capping layer 78 is SiC, and is formed by an AS-ALD processing using a first precursor that contains silicon, such as silane (SiH₄), and using a second precursor that contains carbon, such as methane (CH₄). In embodiments where the capping layer 78 is SiOC, the capping layer 78 may be formed by: forming a layer of SiC using the AS-ALD process discussed above, then oxidizing the layer of SiC into SiOC, thus forming the capping layer 78. The oxidization process may be, e.g., a thermal oxidization process or a plasma process (e.g., ion implantation). Details are the same as or similar to those discussed above, thus not repeated.

The use of AS-ALD process for forming the capping layer 78 obviates the need to perform the plurality of etching processes to remove the capping layer 78 from the sidewalls and the top surfaces of the fin structures 91, which plurality of etching processes are needed if a non-selective ALD process is used to form the capping layer 78. As a result, processing time is reduced and production cost is lowered. The material of the capping layer 78 formed in the present disclosure, such as SiC, SiOC, SiCN, or SiOCN, has a lower dielectric constant than that of the SiN. For example, dielectric constants for the SiC, SiCO, and SiCN layers formed herein may be 4.2, 4.4, and 4.3, respectively, which are lower than the dielectric constant of SiN, which may be larger than 7.5. In addition, the capping layer 78 is much more etch-resistant than the hard mask layer 73 and the liner layer 61. These features advantageously reduce the overall dielectric constant of the STI protection structure 68, reduce RC delay of the device formed, and provides enhanced protection for the STI regions 96.

Next, processing steps same as or similar to those illustrated in FIGS. 14A-23B are performed to form the NSFET device 100A of FIGS. 25A-25C. For example, dummy gate structures 101 are formed over the fin structures 91. Subsequently, sacrificial material 57 replaces the first semiconductor material 52 disposed under the dummy gate structures 101. A replacement gate process is then performed to replace the dummy gate structures 101 with replacement gate structures 123. Skilled artisans, upon reading the present disclosure, would readily be able to apply the processing steps illustrated for the NSFET device 100 to form the NSFET device 100A. FIGS. 25A -25C illustrate the NSFET device 100A after the replacement gate structures 123 are formed. FIGS. 25B and 25C illustrates the cross-sections of the NSFET device 100A along cross-sections F-F and E-E in FIG. 25A.

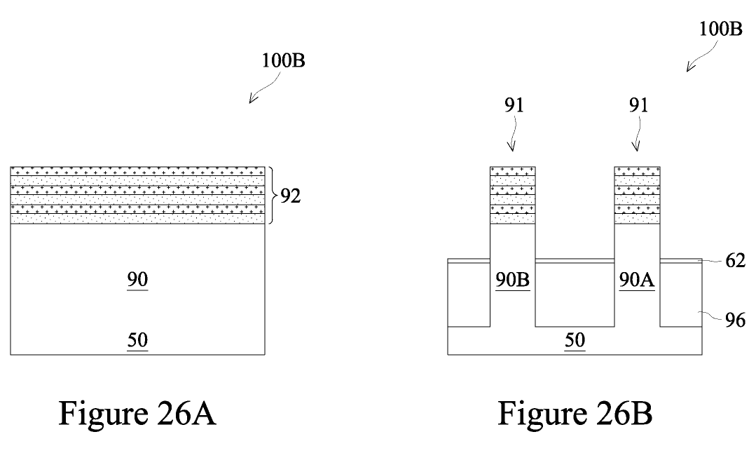

FIGS. 26A, 26B, 27A, 27B, 28A, 28B, 28C, are cross-sectional views of a portion of an NSFET device 100B at various stages of manufacturing, in accordance with yet another embodiment. The NSFET device 100B is similar to the NSFET device 100, but the STI protection structure 68 of the NSFET device 100B has as different layered structure. Details are discussed hereinafter.

FIGS. 26A and 26B illustrate the NSFET device 100B after formation of a seed layer 62 on the STI regions 96. The processing step shown in FIGS. 26A and 26B follows the processing step of FIGS. 3A and 3B.

Referring to FIGS. 26A and 2B, after the processing steps illustrated in FIGS. 3A and 3B, the STI regions 96 are formed, using the same or similar processing as illustrated in FIGS. 4A and 4B. Next, the seed layer 62 is selectively formed on the upper surfaces of the STI regions 96. In some embodiments, the seed layer 62 (or the subsequently formed capping layer 63) is formed of a material such as an aluminum-containing compound, a nitride, or the like. In some embodiments, the seed layer 62 (or the capping layer 63) is formed of a metal nitride. In an embodiment, the seed layer 62 is a layer of aluminum nitride (AlN) formed by a sputtering deposition method. In some embodiments, due to the directional nature (e.g., anisotropic deposition) of the sputtering deposition method, the seed layer 62 is formed mostly on the upper surfaces of the STI regions 96, and little or no seed layer 62 is formed along the sidewalls of the fin structures 91. In some embodiments, the aluminum atoms bond easily with the dangling bonds (e.g., Si-O dangling bonds) at the upper surfaces of the STI regions 96, resulting in selective formation of the seed layer 62 on the upper surfaces of the STI regions 96. In some embodiments, prior to the formation of the seed layer 62, a cleaning process (e.g., an etching process) is performed to remove the native oxide (and the Si-O dangling bonds) from the exterior surfaces of the fin structures 91 (e.g., portions of the fin structures 91 extending above the STI regions 96), in order to facilitate the selective formation of the seed layer 62 on the upper surfaces of the STI regions 96.

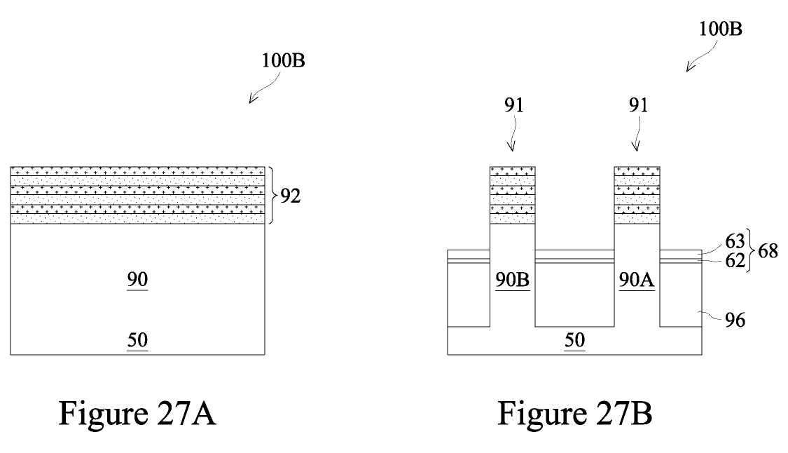

Next, in FIGS. 27A and 27B, the capping layer 63 is selectively formed on the seed layer 62. The seed layer 62 and the capping layer 63 form the STI protection structure 68 of the NSFET device 100B. Notably, the hard mask layer 73 and the liner layer 61 of the NSFET device 100 are not formed in the NSFET device 100B.

In the illustrated embodiment, the capping layer 63 is a layer of aluminum nitride (AlN) formed by an ALD process (e.g., an AS-ALD process). The ALD process is performed using an aluminum-containing precursor, such as trimethylaluminum (TMA) or aluminum chloride (AlCl₃), and using a nitrogen-containing precursor, such as ammonia (NH₃) or nitrogen (N₂). A temperature of the ALD process may be between about 300 Kevin (K) and about 650 K.

In some embodiments, H₂O or O₂ are used in the ALD process for forming the capping layer 63, e.g., as reaction gas or carrier gas, in order to tune various aspects of the ALD process. For example, the presence of oxygen-containing species may enhance the initial nucleation of AlN, leading to more uniform film growth, especially in the early stages of deposition.

Due to the seed layer 62 (e.g., AlN), the deposition rate of aluminum nitride on the seed layer 62 is much higher than other surfaces, such as the sidewalls and the top surfaces of the fin structures 91. In other words, the seed layer 62 promotes selective growth of the capping layer 63 on the seed layer 62, and therefore, there is little or no growth of the capping layer 63 on the sidewalls and the top surfaces of the fin structures 91. In some embodiments, after the ALD process for forming the capping layer 63 is stopped, an etching process, which is optional, is performed to remove the capping layer 63 (if formed) from the sidewalls and the top surfaces of the fin structures 91. A total thickness of the seed layer 62 and the capping layer 63 may be between about 5 nm and about 15 nm, as an example. Although FIG. 27B shows the seed layer 62 and the capping layer 63 as two separate layers, there may or may not be an interface between the seed layer 62 and the capping layer 63. Since the seed layer 62 and the capping layer 63 are formed of a same material (e.g., AlN) in the illustrated embodiment, the seed layer 62 and the capping layer 63 may merge into one layer, and therefore, may also be collectively referred to as a capping layer 68 for the STI regions 96.

Advantage of the disclose STI protection structure 68 of the NSFET device 100B are similar to those discussed above. For example, the AS-ALD processes used to form the seed layer 62 and the capping layer 63 obviate the plurality of etching processes used to remove the seed layer 62 and the capping layer 63 from the sidewalls and the top surfaces of the fin structures 91, if non-selective ALD processes are used. The material of the STI protection structure 68 (e.g., AlN) has a lower dielectric constant (e.g., between about 5.0 and about 9.0) than silicon nitride, and is orders of magnitude (e.g., 100 times or more) more etch-resistant than silicon nitride for the etchant (e.g., hydrofluoric acid) used in the sheet formation process. In other words, compared with the STI protection structure 68’ (see, e.g., FIG. 11B), the disclosed STI protection structure 68 provides much better protection for the STI regions 96 underlying the dummy gate structures 101, while achieving a lower overall (e.g., average) dielectric constant value and reduced RC delay.

Although aluminum nitride is used as an example material for forming the STI protection structure 68 of the NSFET device 100B, other suitable materials, such as aluminum oxynitride (e.g., AlON), titanium oxynitride (e.g., TiON), or platinum (e.g., Pt), may be selectively formed on the upper surfaces of the STI regions 96 to form the STI protection structure 68 of the NSFET device 100B. A few examples are discussed hereinafter.

In some embodiments, a layer of aluminum oxynitride (AlON) is selectively formed on the upper surfaces of the STI regions 96 as the STI protection structure 68. For example, an ALD process is performed using an aluminum-containing precursor (e.g., aluminum dimethyl isopropoxide (DMAI)) and an oxygen-containing precursor (e.g., H₂O) to form a layer of aluminum oxide (e.g., Al₂O₃) on the upper surfaces of the STI regions 96. In this example, no seed layer is used, and the layer of aluminum oxide is formed directly on the STI regions 96 using the ALD process. The layer of aluminum oxide is then converted into a layer of aluminum oxynitride by doping the layer of aluminum oxide with nitrogen ions (e.g., by performing an implantation process). Due to the aluminum atoms bonding easily with the Si-O dangling bonds at the upper surfaces of the STI regions 96, the layer of aluminum oxynitride is formed selectively on the STI regions 96. The STI protection structure 68 formed in this example is a single layer of aluminum oxynitride.

In some embodiments, a layer of titanium oxynitride (TiON) is selectively formed on the upper surfaces of the STI regions 96 as the STI protection structure 68. For example, an ALD process is performed using a titanium-containing precursor (e.g., TiCl₄) and an oxygen-containing precursor (e.g., H₂O) to form a layer of titanium oxide (e.g., TiO₂) on the upper surfaces of the STI regions 96. In this example, no seed layer is used, and the layer of titanium oxide is formed directly on the STI regions 96 using the ALD process. The layer of titanium oxide is then converted into a layer of titanium oxynitride by doping the layer of titanium oxide with nitrogen ions (e.g., by performing an implantation process). Due to the titanium atoms bonding easily with the Si-O dangling bonds at the upper surfaces of the STI regions 96, the layer of titanium oxynitride is formed selectively on the STI regions 96. The STI protection structure 68 formed in this example is a single layer of titanium oxynitride.

In some embodiments, a layer of platinum (Pt) is selectively formed on the upper surfaces of the STI regions 96 as the STI protection structure 68. For example, a passivation layer is formed along the sidewalls and the top surfaces of the portions of the fin structures 91 that protrudes above the STI regions 96. The passivation layer may be formed by using 1-octadecene. In some embodiments, 1-octadecene reacts with the surface hydrides (may also be referred to as silicon hydrides, or Si-H groups) at the sidewalls and the top surfaces of the fin structures 91 and forms a monolayer of long-chain hydrocarbons covalently bonded to the silicon surface. This monolayer is hydrophobic and can act as an effective passivation layer or blocking layer, which prevents the formation of platinum in this example. In some embodiments, before 1-octadecene is applied to form the passivation layer, a surface cleaning process is performed to achieve a clean silicon surface with silicon hydrides. This may be achieved by treating the sidewalls and the top surfaces of the fin structures 91 with hydrofluoric acid (HF) to remove native oxide and create hydrogen-terminated surfaces. Next, the layer of platinum is selectively formed on the upper surfaces of the STI regions 96 as the STI protection structure 68. After the layer of platinum is formed, the passivation layer is removed, e.g., by a thermal process or a plasma treatment (e.g., using oxygen plasma or hydrogen plasma). The STI protection structure 68 formed in this example is a single layer of platinum.

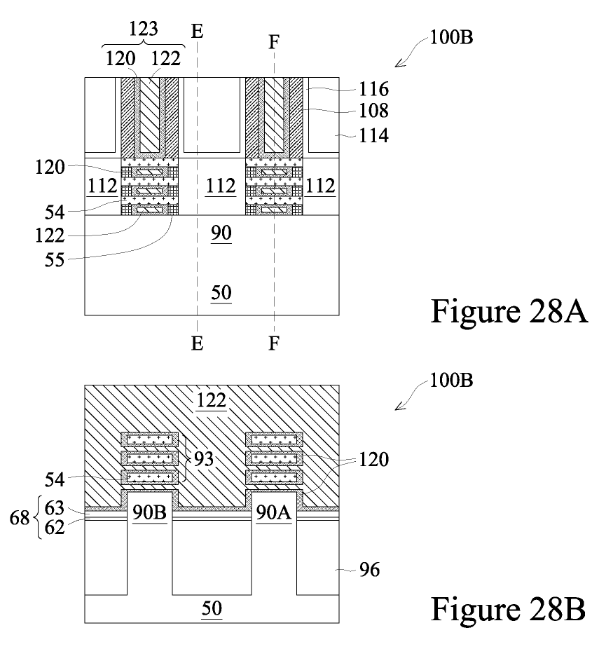

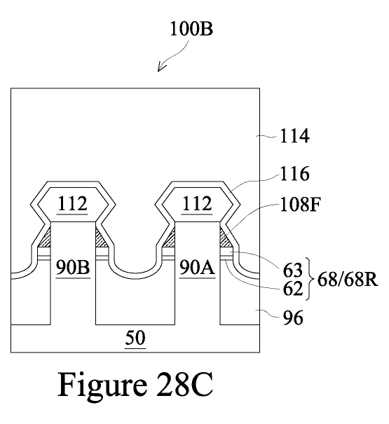

Next, processing steps same as or similar to those illustrated in FIGS. 14A-23B are performed to form the NSFET device 100B of FIGS. 28A-28C. For example, dummy gate structures 101 are formed over the fin structures 91. Subsequently, sacrificial material 57 replaces the first semiconductor material 52 disposed under the dummy gate structures 101. A replacement gate process is then performed to replace the dummy gate structures 101 with replacement gate structures 123. Skilled artisans, upon reading the present disclosure, would readily be able to apply the processing steps illustrated for the NSFET device 100 to form the NSFET device 100B. FIGS. 28A -28C illustrate the NSFET device 100B after the replacement gate structures 123 are formed. FIGS. 28B and 28C illustrates the cross-sections along cross-sections F-F and E-E in FIG. 28A. Note that in FIGS. 28A-28C, the STI protection structure 68 is illustrated to have the same structure shown in FIG. 27B, e.g., with the seed layer 62 and the capping layer 63, with the understanding that the seed layer 62 and the capping layer 63 may merge into one layer, and that the STI protection structure 68 may be formed as a single layer of a suitable material, such as AlON, TiON, or Pt, as discussed above.

Advantages are achieved by the disclosed embodiments. For example, the use of the DOI process reduces intermixing between germanium and silicon, and provides significantly higher etching selectivity (e.g., > 10000) between the disposable material 57 and the second semiconductor material 54. As a result, when the sacrificial material 57 is removed to form the nanostructures 54, there is little or no damage to the nanostructures. As another example, the disclosed STI protection structure 68 achieves high level of etch resistance to the etching process used in the sheet formation process, and protects the STI regions 96 (e.g., portions directly under the dummy gates) during the removal of the sacrificial material 57, and as a result, loss of the STI region 96 is avoided or reduced, which reduces the parasitic capacitance of the replacement gate structure 123 and improves device performance. As yet another example, the remaining portions 68R of the STI protection structure 68 under the fin spacers 108F prevents or reduces the likelyhood of the fins 90 collapsing or un-intended growth/merging of source/drain material due to over-etching of the STI regions 96 caused by etching process used to form source/drain openings.

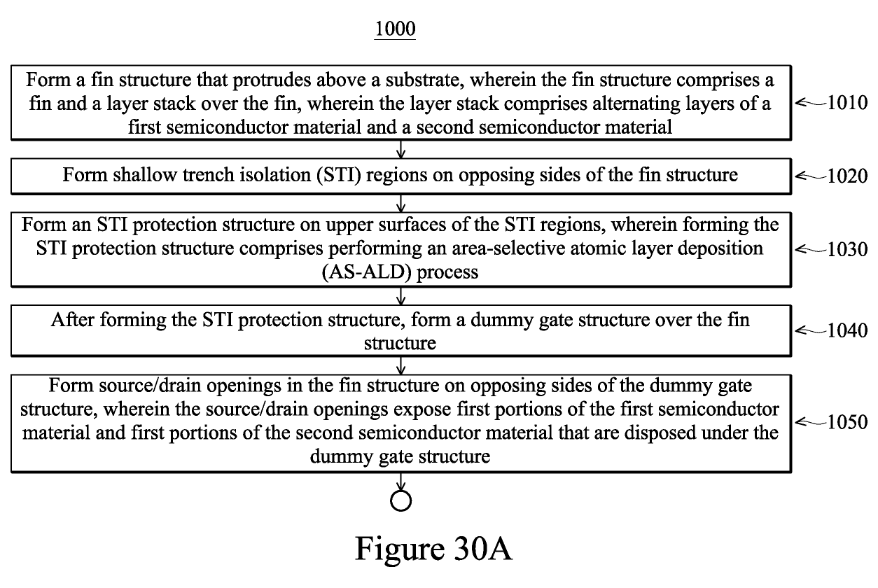

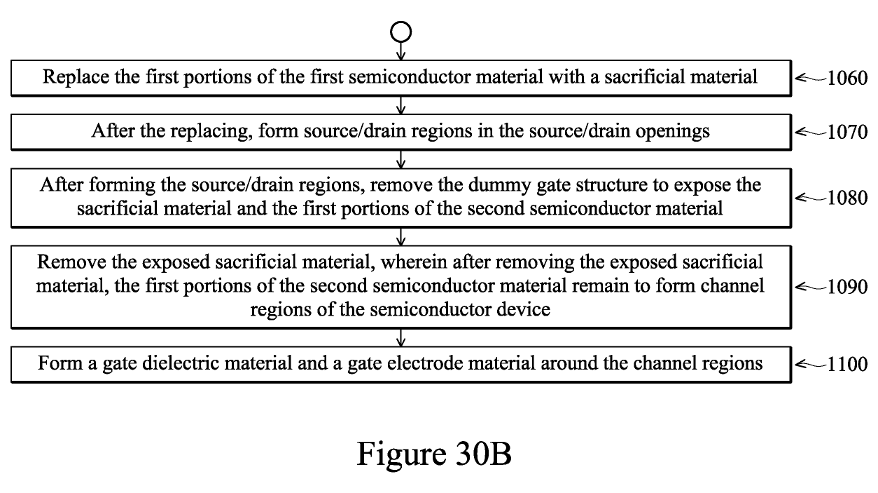

FIGS. 30A and 30B together illustrate a flow chart of a method 1000 of forming a semiconductor device, in accordance with some embodiments. It should be understood that the embodiment method shown in FIGS. 30A and 30B is merely an example of many possible embodiment methods. One of ordinary skill in the art would recognize many variations, alternatives, and modifications. For example, various steps as illustrated in FIGS. 30A and 30B may be added, removed, replaced, rearranged, or repeated.

Referring to FIGS. 30A and 30B, at block 1010, a fin structure that protrudes above a substrate is formed, wherein the fin structure comprises a fin and a layer stack over the fin, wherein the layer stack comprises alternating layers of a first semiconductor material and a second semiconductor material. At block 1020, shallow trench isolation (STI) regions are formed on opposing sides of the fin structure. At block 1030, an STI protection structure is formed on upper surfaces of the STI regions, wherein forming the STI protection structure comprises performing an area-selective atomic layer deposition (AS-ALD) process. At block 1040, after forming the STI protection structure, a dummy gate structure is formed over the fin structure. At block 1050, source/drain openings are formed in the fin structure on opposing sides of the dummy gate structure, wherein the source/drain openings expose first portions of the first semiconductor material and first portions of the second semiconductor material that are disposed under the dummy gate structure. At block 1060, the first portions of the first semiconductor material is replaced with a sacrificial material. At block 1070, after the replacing, source/drain regions are formed in the source/drain openings. At block 1080, after forming the source/drain regions, the dummy gate structure is removed to expose the sacrificial material and the first portions of the second semiconductor material. At block 1090, the exposed sacrificial material is removed, wherein after removing the exposed sacrificial material, the first portions of the second semiconductor material remain to form channel regions of the semiconductor device. At block 1100, a gate dielectric material and a gate electrode material are formed around the channel regions.

In an embodiment, a method of forming a semiconductor device includes: forming a fin structure that protrudes above a substrate, wherein the fin structure comprises a fin and a layer stack over the fin, wherein the layer stack comprises alternating layers of a first semiconductor material and a second semiconductor material; forming shallow trench isolation (STI) regions on opposing sides of the fin structure; forming an STI protection structure on upper surfaces of the STI regions, wherein forming the STI protection structure comprises performing an area-selective atomic layer deposition (AS-ALD) process; after forming the STI protection structure, forming a dummy gate structure over the fin structure; forming source/drain openings in the fin structure on opposing sides of the dummy gate structure, wherein the source/drain openings expose first portions of the first semiconductor material and first portions of the second semiconductor material that are disposed under the dummy gate structure; replacing the first portions of the first semiconductor material with a sacrificial material; after the replacing, forming source/drain regions in the source/drain openings; after forming the source/drain regions, removing the dummy gate structure to expose the sacrificial material and the first portions of the second semiconductor material; removing the exposed sacrificial material, wherein after removing the exposed sacrificial material, the first portions of the second semiconductor material remain to form channel regions of the semiconductor device; and forming a gate dielectric material and a gate electrode material around the channel regions. In an embodiment, forming the STI protection structure comprises: forming a liner layer along the upper surfaces of the STI regions and along sidewalls of the fin structure; forming a hard mask layer over the line layer, wherein the liner layer extends along sidewalls of the hard mask layer; and selectively forming a first capping layer over the line layer and the hard mask layer using the AS-ALD process. In an embodiment, the AS-ALD process forms the first capping layer over the line layer and the hard mask layer but not along the sidewalls of the fin structure and an upper surface of the fin structure. In an embodiment, the liner layer, the hard mask layer, and the first capping layer are formed of a first material, a second material, and a third material, respectively, wherein the first material, the second material, and the third material have a first etch rate, a second etch rate, and a third etch rate, respectively, for an etching process used for removing the exposed sacrificial material, wherein the third etch rate is smaller than the second etch rate, and the second etch rate is smaller than the first etch rate. In an embodiment, the method further includes, after forming the hard mask layer and before forming the first capping layer, selectively forming a passivation layer along exterior surfaces of the fin structure, wherein the passivation layer hinders formation of the first capping layer on the passivation layer. In an embodiment, forming the passivation layer comprises performing a vapor-phase deposition process using dimethylamine-trimethylsilane. In an embodiment, forming the passivation layer comprises treating the fin structure with a plasma process, wherein the plasma process turns the exterior surfaces of the fin structure into hydrophobic surfaces. In an embodiment, the method further includes, after forming the first capping layer, selectively forming a second capping layer over the first capping layer using another AS-ALD process. In an embodiment, forming the STI protection structure comprises selectively forming a capping layer on the STI regions using the AS-ALD process, wherein the capping layer contacts and extends along the upper surfaces of the STI regions. In an embodiment, the capping layer is formed of a first material, wherein selectively forming the capping layer comprises: selectively forming a first layer of the first material on the upper surfaces of the STI regions using a sputtering deposition method, wherein exterior surfaces of the fin structure are exposed by the first layer of the first material; and after selectively forming the first layer of the first material, forming a second layer of the first material on the first layer of the first material using an ALD deposition method. In an embodiment, selectively forming the capping layer further comprises, before selectively forming the first layer of the first material, performing an etching process to remove native oxide on the exterior surfaces of the fin structure.

In an embodiment, a method of forming a semiconductor device includes: forming a fin structure that protrudes above shallow trench isolation (STI) regions, wherein the STI regions are over a substrate and on opposing sides of the fin structure, wherein the fin structure comprises a fin and a layer stack over the fin, wherein the layer stack comprises alternating layers of a first semiconductor material and a second semiconductor material; selectively forming an STI protection structure on upper surfaces of the STI regions; after the selectively forming, forming a dummy gate structure over the fin structure; forming source/drain openings in the fin structure on opposing sides of the dummy gate structure; after forming the source/drain openings, replacing the first semiconductor material disposed under the dummy gate structure with a sacrificial material; after the replacing, forming source/drain regions in the source/drain openings; forming an interlayer dielectric (ILD) layer over the source/drain regions and around the dummy gate structure; removing the dummy gate structure to form a gate trench in the ILD layer, wherein the gate trench exposes the sacrificial material and a first portion of the second semiconductor material; selectively removing the exposed sacrificial material, wherein after the selectively removing, the first portion of the second semiconductor material form nanostructures; and forming a replacement gate structure around the nanostructures. In an embodiment, selectively forming the STI protection structure comprises: forming a liner layer along the upper surfaces of the STI regions and along portions of sidewalls of the fin structure; forming a hard mask layer on the line layer, wherein the liner layer surrounds the hard mask layer; and selectively forming a first capping layer on the line layer and the hard mask layer using an area-selective atomic layer deposition (AS-ALD) process. In an embodiment, the method further includes, after forming the hard mask layer and before selectively forming the first capping layer, forming a passivation layer along exterior surfaces of the fin structure, wherein an upper surface of the hard mask layer distal from the substrate is exposed by the passivation layer. In an embodiment, selectively removing the exposed sacrificial material comprises performing an etching process, wherein the first capping layer is more etch-resistant to the etching process than the hard mask layer, and the hard mask layer is more etch-resistant to the etching process than the liner layer. In an embodiment, the method further includes, after selectively forming the first capping layer, selectively forming a second capping layer different from the first capping layer on the first capping layer using another AS-ALD process. In an embodiment, the STI protection structure is formed of a first material, wherein selectively forming the STI protection structure comprises: sputtering a first layer of the first material on the upper surfaces of the STI regions, wherein exterior surfaces of the fin structure are exposed by the first layer of the first material; and after the sputtering, selectively forming a second layer of the first material on the first layer of the first material using an ALD deposition method.

In an embodiment, a semiconductor device includes: a substrate; a fin protruding above the substrate; shallow trench isolation (STI) regions on opposing sides of fin; an STI protection structure contacting and extending along upper surfaces of the STI regions; source/drain regions over the fin; nanostructures over the fin and between the source/drain regions; and a gate structure between the source/drain regions and around the nanostructures, wherein a gate dielectric material of the gate structure contacts and extends along an upper surface of the STI protection structure distal from the substrate. In an embodiment, the STI protection structure comprises: a liner layer along sidewalls of the fin and along the upper surfaces of the STI regions; a hard mask layer over the liner layer, wherein the liner layer extends along sidewalls of the hard mask layer; and a capping layer over the hard mask layer and the liner layer. In an embodiment, the STI protection structure is a single layer of a first material, wherein the first material is different from a second material of the STI regions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a fin structure that protrudes above a substrate, wherein the fin structure comprises a fin and a layer stack over the fin, wherein the layer stack comprises alternating layers of a first semiconductor material and a second semiconductor material;
forming a shallow trench isolation (STI) region over the substrate and adjacent to the fin structure;
forming an STI protection structure over an upper surface of the STI region distal from the substrate, wherein forming the STI protection structure comprises:
forming a liner layer over the STI region, wherein a first portion of the liner layer extends along the upper surface of the STI region, and a second portion of the liner layer extends along a sidewall of the fin structure;
forming a hard mask layer over the liner layer, wherein a bottom surface of the hard mask layer extends along the first portion of the liner layer, and a sidewall of the hard mask layer extends along the second portion of the liner layer; and
selectively forming a first capping layer over the hard mask layer and the liner layer;
after forming the STI protection structure, forming a dummy gate structure over the fin structure and the STI protection structure;
replacing first portions of the first semiconductor material disposed under the dummy gate structure with a sacrificial material;
forming source/drain regions on opposing sides of the dummy gate structure; and
after forming the source/drain regions, replacing the dummy gate structure with a replacement gate structure.

2. The method of claim 1, wherein replacing the first portions of the first semiconductor material comprises:
forming source/drain openings in the fin structure on opposing sides of the dummy gate structure, wherein the source/drain openings expose the first portions of the first semiconductor material and first portions of the second semiconductor material that are disposed under the dummy gate structure, wherein the source/drain regions are formed in the source/drain openings;
performing an isotropic etching process to remove the first portions of the first semiconductor material and form empty spaces between the first portions of the second semiconductor material; and
forming the sacrificial material in the empty spaces.

3. The method of claim 2, wherein replacing the dummy gate structure comprises:
removing the dummy gate structure to expose the sacrificial material and the first portions of the second semiconductor material;
selectively removing the sacrificial material using an etching chemical, wherein after the selectively removing, the first portions of the second semiconductor material remain and form channel layers; and
forming a gate dielectric material and a gate electrode material around the channel layers.

4. The method of claim 3, wherein the liner layer, the hard mask layer, and the first capping layer are formed of a first dielectric material, a second dielectric material, and a third dielectric material, respectively, wherein the first dielectric material, the second dielectric material, and the third dielectric material have a first etch rate, a second etch rate, and a third etch rate, respectively, for the etching chemical, wherein the third etch rate is slower than the second etch rate, and the second etch rate is slower than the first etch rate.

5. The method of claim 4, wherein the first dielectric material comprises silicon oxide, the second dielectric material comprises silicon nitride, and the third dielectric material comprises an aluminum-containing compound.

6. The method of claim 1, wherein forming the liner layer and forming the hard mask layer comprise:
forming a liner material along sidewalls of the fin structure, along an upper surface of the fin structure, and along the upper surface of the STI region;
forming a hard mask material over the liner material and along the sidewalls of the fin structure, along the upper surface of the fin structure, and along the upper surface of the STI region; and
performing multiple etching processes using multiple etching chemicals to recess the liner material and the hard mask material such that the upper surface of the fin structure and upper sidewalls of the fin structure are exposed by the liner material and the hard mask material while the upper surface of the STI region is covered by the liner material and the hard mask material, wherein after performing the multiple etching processes, a remaining portion of the liner material and a remaining portion of the hard mask material form the liner layer and the hard mask layer, respectively.

7. The method of claim 1, wherein the liner layer and the hard mask layer cover the upper surface of the STI region, and expose an upper surface of the fin structure distal from the substrate and an upper portion of a sidewall of the fin structure, wherein selectively forming the first capping layer comprises:
selectively forming a passivation layer along the upper surface of the fin structure and the upper portion of the sidewall of the fin structure;
selectively forming the first capping layer on an upper surface of the liner layer and an upper surface of the hard mask layer, wherein during selectively forming the first capping layer, the passivation layer hinders formation of the first capping layer on the passivation layer; and
after selectively forming the first capping layer, removing the passivation layer.

8. The method of claim 7, wherein selectively forming the passivation layer comprises selectively forming a monolayer of a passivation material along the upper surface of the fin structure and along the upper portion of the sidewall of the fin structure by performing a vapor-phase deposition process.

9. The method of claim 7, wherein selectively forming the passivation layer comprises performing a plasma process to treat the upper surface of the fin structure and the upper portion of the sidewall of the fin structure, wherein the plasma process is performed using a nitrogen-containing gas source.

10. The method of claim 7, wherein forming the STI protection structure further comprises, after forming the first capping layer and before removing the passivation layer, selectively forming a second capping layer over the first capping layer.

11. The method of claim 10, wherein the first capping layer is formed of an aluminum-containing material, and the second capping layer is formed of a carbon-containing material.

12. A method of forming a semiconductor device, the method comprising:
forming a fin structure that protrudes above shallow trench isolation (STI) regions, wherein the STI regions are over a substrate and on opposing sides of the fin structure, wherein the fin structure comprises a fin and a layer stack over the fin, wherein the layer stack comprises alternating layers of a first semiconductor material and a second semiconductor material;
forming an STI protection structure on upper surfaces of the STI regions distal from the substrate, comprising:
forming a dielectric structure on the upper surfaces of the STI regions, wherein the dielectric structure comprises a hard mask layer and a liner layer between the hard mask layer and the STI regions, wherein the liner layer extends along a bottom surface of the hard mask layer and along sidewalls of the hard mask layer, wherein a first portion of the fin structure protrudes above the dielectric structure; and
selectively forming a capping layer on an upper surface of the dielectric structure;
forming a dummy gate structure over the fin structure and the STI protection structure;
forming source/drain openings in the fin structure on opposing sides of the dummy gate structure;
after forming the source/drain openings, replacing the first semiconductor material disposed under the dummy gate structure with a sacrificial material;
after the replacing, forming source/drain regions in the source/drain openings; and
after forming the source/drain regions, replacing the dummy gate structure with a replacement gate structure.

13. The method of claim 12, wherein replacing the dummy gate structure comprises:
forming an interlayer dielectric (ILD) layer over the source/drain regions and around the dummy gate structure;
removing the dummy gate structure to form a gate trench in the ILD layer, wherein the gate trench exposes the sacrificial material and first portions of the second semiconductor material;
selectively removing the exposed sacrificial material, wherein after selectively removing the exposed sacrificial material, the first portions of the second semiconductor material form nanostructures; and
forming the replacement gate structure around the nanostructures.

14. The method of claim 12, wherein forming the STI protection structure further comprises:
after forming the dielectric structure and before selectively forming the capping layer, selectively forming a passivation layer on exterior surfaces of the first portion of the fin structure, wherein during selectively forming the capping layer, the passivation layer hinders formation of the capping layer on the passivation layer; and
after selectively forming the capping layer and before forming the dummy gate structure, removing the passivation layer.

15. The method of claim 14, wherein the passivation layer is a monolayer of a passivation material formed by performing a vapor-phase deposition process.

16. The method of claim 14, wherein the passivation layer is formed by treating the exterior surfaces of the first portion of the fin structure with a plasma process.

17. The method of claim 16, wherein the plasma process is performed using a gas source comprising a nitrogen-containing gas and a hydrogen gas, wherein a mixing ratio between the nitrogen-containing gas and the hydrogen gas is tuned during the plasma process to adjust a surface reactivity of the first portion of the fin structure.

18. A method of forming a semiconductor device, the method comprising:
forming a fin structure that protrudes above shallow trench isolation (STI) regions, wherein the STI regions are on opposing sides of the fin structure, wherein the fin structure comprises a fin and a layer stack over the fin, wherein the layer stack comprises alternating layers of a first semiconductor material and a second semiconductor material;
forming an STI protection structure on upper surfaces of the STI regions, comprising:
selectively forming a seed layer on the upper surfaces of the STI regions; and
selectively forming a capping layer on the seed layer;
forming a dummy gate structure over the fin structure and the STI protection structure;
forming source/drain openings in the fin structure on opposing sides of the dummy gate structure;
after forming the source/drain openings, replacing the first semiconductor material disposed under the dummy gate structure with a sacrificial material;
after the replacing, forming source/drain regions in the source/drain openings; and
after forming the source/drain regions, replacing the dummy gate structure with a replacement gate structure.

19. The method of claim 18, wherein selectively forming the seed layer comprises performing a sputtering process to selectively form the seed layer on the upper surfaces of the STI regions, wherein selectively forming the capping layer comprises performing an atomic layer deposition process to selectively form the capping layer on the seed layer.

20. The method of claim 19, wherein the seed layer and the capping layer are formed of a same aluminum-containing compound material.
